(19) United States
(12) Patent Application Publication
(10) Pub. No.: US 2024/0334705 A1
(43) Pub. Date: Oct. 3, 2024

(54) SEMICONDUCTOR DEVICE INCLUDING BACKSIDE TRANSISTORS

(71) Applicant: SK hynix Inc., Icheon-si (KR)

(72) Inventors: Chang Woo KANG, Icheon-si (KR); Jin Ho KIM, Icheon-si (KR)

(21) Appl. No.: 18/457,948

(22) Filed: Aug. 29, 2023

(30) Foreign Application Priority Data
Mar. 30, 2023 (KR) 10-2023-0041961

(51) Int. Cl. H10B 43/40; H01L 23/00; H01L 25/00; H01L 25/065; H01L 25/18; H10B 43/27; H10B 43/35; H10B 80/00

(52) U.S. Cl. CPC H10B 43/40; H01L 24/08; H01L 24/80; H01L 25/0657; H01L 25/18; H01L 25/50; H10B 43/27; H10B 43/35; H10B 80/00; H01L 2224/08145; H01L 2224/80006; H01L 2224/80895; H01L 2224/80896; H01L 2924/1431; H01L 2924/14511

(57) ABSTRACT

A semiconductor device may include a first substrate having a first surface and a second surface which faces opposite the first surface. A stack structure disposed on the first surface of the first substrate and including a plurality of interlayer insulating layers and a plurality of horizontal wiring layers which are alternately stacked and a plurality of channel structures which pass through the plurality of interlayer insulating layers and the plurality of horizontal wiring layers may be provided. A plurality of upper transistors may be disposed on the second surface of the first substrate. A logic structure disposed on the stack structure and including a plurality of lower transistors may be provided.

### CROSS-REFERENCE TO RELATED APPLICATION

The present application claims priority under 35 U.S.C. § 119 (a) to Korean Patent Application No. 10-2023-0041961 filed in the Korean Intellectual Property Office on Mar. 30, 2023, which is incorporated herein by reference in its entirety.

### BACKGROUND

### 1. Technical Field

Various embodiments generally relate to a semiconductor device including backside transistors and a method for forming the same.

### 2. Related Art

In accordance with the need for light, thin and compact semiconductor devices, technologies using a stack structure are being researched. A plurality of memory cells may be disposed in three-dimensions in the stack structure. The plurality of memory cells may be connected to a logic circuit. The logic circuit may control erase (or initialize), write and read operations for the plurality of memory cells.

As the number of electrode layers in the stack structure increases, the number of memory cells may increase. Due to an increase in the number of memory cells, the number of active/passive elements required for the configuration of the logic circuit may also increase. An increase in the number of active/passive elements may serve as an obstacle to high integration of semiconductor devices.

### SUMMARY

Various embodiments are directed to providing a semiconductor device that is advantageous for high integration and has excellent electrical characteristics, and a method for forming the same.

A semiconductor device based on the embodiment of the disclosed technology may include a first substrate having a first surface and a second surface facing opposite the first surface. A stack structure disposed on the first surface of the first substrate and including a plurality of interlayer insulating layers and a plurality of horizontal wiring layers that are alternately stacked and a plurality of channel structures that pass through the plurality of interlayer insulating layers and the plurality of horizontal wiring layers may be provided. A plurality of upper transistors may be disposed on the second surface of the first substrate. A logic structure disposed on the stack structure and including a plurality of lower transistors may be provided.

A semiconductor device based on the embodiment of the disclosed technology may include a first substrate having a first surface and a second surface that faces opposite the first surface. A stack structure disposed on the first surface of the first substrate and including a plurality of interlayer insulating layers and a plurality of horizontal wiring layers that are alternately stacked, and a plurality of channel structures that pass through the plurality of interlayer insulating layers and the plurality of horizontal wiring layers may be provided. The stack structure may include a cell area and a connection area that is continuous to the cell area. The plurality of channel structures may be disposed in the cell area. A plurality of upper transistors may be disposed on the second surface of the first substrate. A common source line disposed at substantially the same horizontal level as the first substrate on the stack structure and connected to the plurality of channel structures may be provided. A logic structure bonded onto the stack structure and including a plurality of lower transistors may be provided.

A semiconductor device based on the embodiment of the disclosed technology may include a first substrate having a first surface and a second surface that faces opposite the first surface. A stack structure disposed on the first surface of the first substrate and including a plurality of interlayer insulating layers and a plurality of horizontal wiring layers that are alternately stacked and a plurality of channel structures that pass through the plurality of interlayer insulating layers and the plurality of horizontal wiring layers may be provided. A plurality of upper transistors may be disposed on the second surface of the first substrate. A common source line disposed at substantially the same horizontal level as the first substrate on the stack structure and connected to the plurality of channel structures may be provided.

According to the embodiments of the disclosed technology, a plurality of upper transistors which are formed adjacent to the backside of a first substrate and a plurality of lower transistors which are formed on a second substrate may be provided. At least a part of a pass transistor circuit, a block selection circuit, a page buffer circuit and a peripheral circuit may be distributedly disposed inside a logic structure bonded to the lower part of a stack structure and adjacent to the backside of the first substrate preserved on the stack structure. Due to the disposition of the plurality of upper transistors, the densities of the plurality of lower transistors and interconnections may decrease.

It is possible to implement a semiconductor device which is advantageous for high integration and has excellent electrical characteristics.

### BRIEF DESCRIPTION OF THE DRAWINGS

FIG. 1 is a cross-sectional view of a semiconductor device according to an embodiment of the disclosure.

FIGS. 2 to 9 are partial views illustrating partial configurations of FIG. 1.

FIGS. 10 to 12 are cross-sectional views of semiconductor devices according to embodiments of the disclosure.

FIG. 13 is a partial view of a partial configuration of FIG. 12.

FIG. 14 is a layout diagram of a semiconductor device according to an embodiment of the disclosure.

FIGS. 15 to 27 are cross-sectional views illustrating a method for forming a semiconductor device according to an embodiment of the disclosure.

FIG. 28 is a schematic configuration diagram of a storage device according to an embodiment of the disclosure.

FIG. 29 is a block diagram schematically illustrating a memory of FIG. 28.

### DETAILED DESCRIPTION

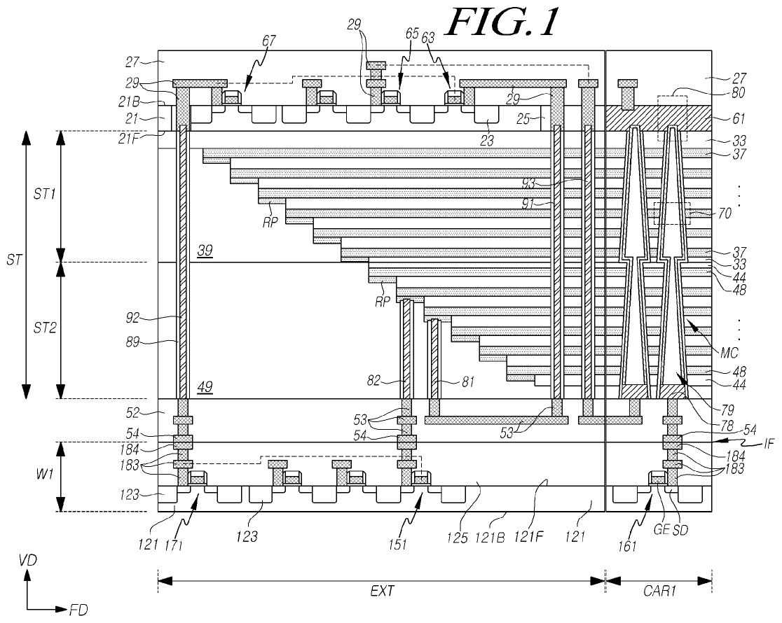

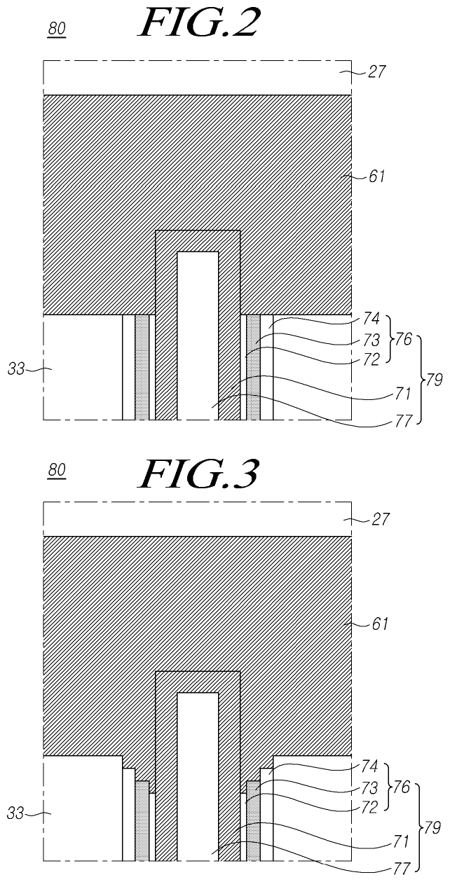

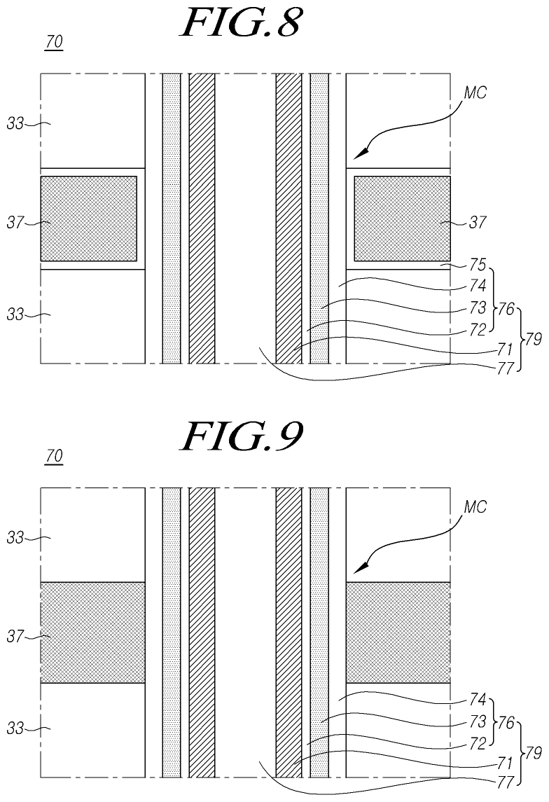

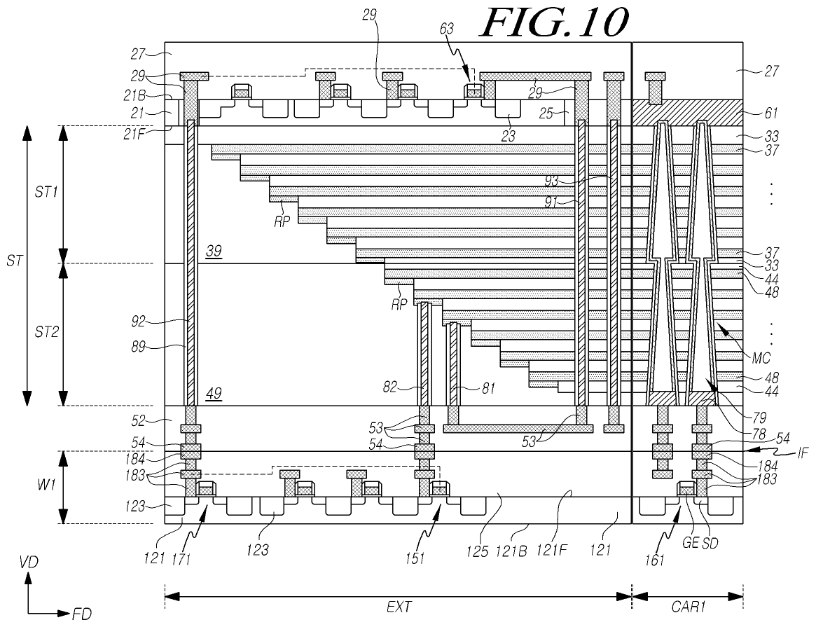

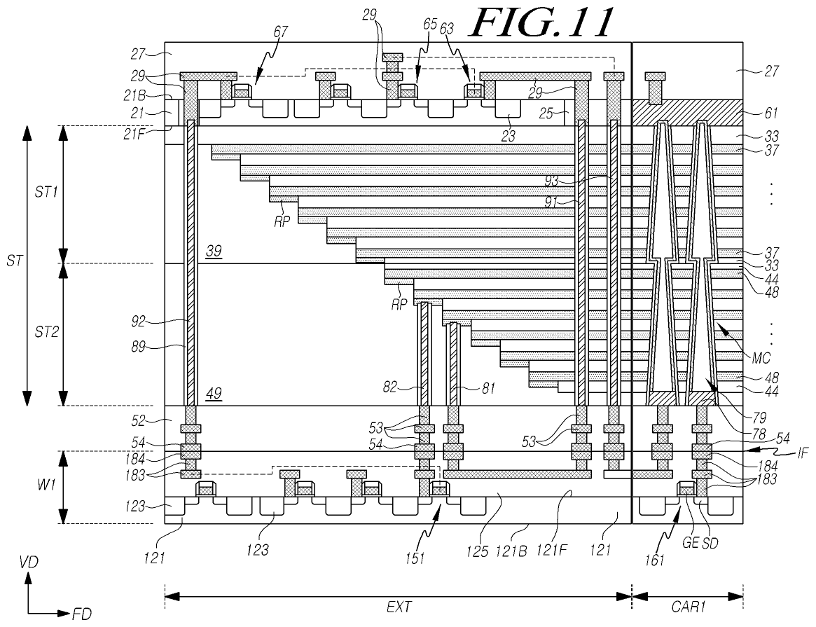

FIG. 1 is a cross-sectional view of a semiconductor device according to an embodiment of the disclosure, FIGS. 2 to 7 are partial views illustrating a partial configuration 80 of FIG. 1, and FIGS. 8 and 9 are partial views illustrating a partial configuration 70 of FIG. 1. A semiconductor device according to embodiments of the disclosed technology may include a 3D flash memory such as a VNAND. The semiconductor devices based on embodiments of the disclosed technology may include a shared slim structure.

Referring to FIG. 1, a semiconductor device may include a first substrate 21, an upper isolation layer 23, an isolation insulating pattern 25, an upper insulating layer 27, a plurality of upper interconnections 29, an intermediate insulating layer 52, a plurality of intermediate interconnections 53, a plurality of upper pads 54, a common source line 61, a plurality of upper transistors 63, 65 and 67, a stack structure ST, and a logic structure W1. The first substrate 21 may include a first surface 21F and a second surface 21B which face opposite each other. The first surface 21F may be referred to as a frontside, and the second surface 21B may be referred to as a backside. Each of the plurality of upper transistors 63, 65 and 67 may be referred to as a backside transistor. The stack structure ST may include a first cell area CAR1 and a connection area EXT. The connection area EXT may be continuous to a side of the first cell area CAR1. The stack structure ST may be bonded over the logic structure W1. An interface IF may be formed between the logic structure W1 and the stack structure ST.

In an embodiment, the connection area EXT may be referred to as a slim or a slim area. A first direction FD and a second direction VD may be defined. The first direction FD may be parallel to the upper surfaces and lower surfaces of the first substrate 21 and a second substrate 121. The second direction VD may intersect with the first direction FD. The second direction VD may be perpendicular to the upper surfaces and lower surfaces of the first and second substrates 21 and 121.

The stack structure ST may include a first stack structure ST1, a second stack structure ST2, a plurality of channel structures 79, a plurality of contact plugs 81 and 82, contact spacers 89, and a plurality of through electrodes 91, 92 and 93. The first stack structure ST1 may include a plurality of first interlayer insulating layers 33, a plurality of first horizontal wiring layers 37, a plurality of connection pads RP, and a first buried insulating layer 39. The second stack structure ST2 may include a plurality of second interlayer insulating layers 44, a plurality of second horizontal wiring layers 48, a plurality of connection pads RP, and a second buried insulating layer 49.

The logic structure W1 may include the second substrate 121, a lower isolation layer 123, a lower insulating layer 125, a plurality of lower transistors 151, 161 and 171, a plurality of lower interconnections 183, and a plurality of lower pads 184. The second substrate 121 may include a first surface 121F and a second surface 121B that face opposite each other. The first surface 121F may be referred to as an upper surface or a frontside, and the second surface 121B may be referred to as a lower surface or a backside.

Each of the plurality of upper transistors 63, 65 and 67 and the plurality of lower transistors 151, 161 and 171 may include an NMOS transistor or a PMOS transistor. Each of the plurality of upper transistors 63, 65 and 67 and the plurality of lower transistors 151, 161 and 171 may include a gate electrode GE and a pair of source and drain areas SD. Each of the plurality of upper transistors 63, 65 and 67 and the plurality of lower transistors 151, 161 and 171 may include a planar transistor, a recess channel transistor, a vertical transistor, a fin field effect transistor (finFET), a gate all around (GAA) transistor, a multi-bridge channel transistor, or a combination thereof.

In an embodiment, the plurality of lower transistors 151, 161 and 171 may include a first lower pass transistor 151, a first lower page buffer transistor 161 and a first lower block switch transistor 171. The plurality of lower transistors 151, 161 and 171 may be disposed between the second substrate 121 and the interface IF. The plurality of lower transistors 151, 161 and 171 may be formed on or adjacent to the first surface 121F of the second substrate 121. A plurality of each of the first lower pass transistor 151, the first lower page buffer transistor 161 and the first lower block switch transistor 171 may be repeatedly disposed or arranged. In an embodiment, the first lower pass transistor 151 and the first lower block switch transistor 171 may be aligned in the second direction VD at a lower part of the connection area EXT, and the first lower page buffer transistor 161 may be aligned in the second direction VD with the first lower pass transistor 151 and the first lower block switch transistor 171 at a lower part of the first cell area CAR1.

The plurality of upper transistors 63, 65 and 67 may include a first upper pass transistor 63, a first upper page buffer transistor 65 and a first upper block switch transistor 67. The plurality of upper transistors 63, 65 and 67 may be formed on or adjacent to the second surface 21B of the first substrate 21. The first substrate 21 may be disposed between the plurality of upper transistors 63, 65 and 67 and the first stack structure ST1. The plurality of upper transistors 63, 65 and 67 may be disposed on the second surface 21B of the first substrate 21. The plurality of upper transistors 63, 65 and 67 may be aligned in the second direction VD at an upper part of the connection area EXT. A plurality of each of the first upper pass transistor 63, the first upper page buffer transistor 65 and the first upper block switch transistor 67 may be repeatedly disposed or arranged.

In an embodiment, the common source line 61 may be disposed at substantially the same horizontal level, i.e., at the same level in the second direction VD, as the first substrate 21. The first substrate 21 may be aligned in the second direction VD at an upper part of the connection area EXT. The common source line 61 may be aligned in the second direction VD at an upper part of the first cell area CAR1. The first surface 21F of the first substrate 21 and the lower surface of the common source line 61 may form substantially the same plane. The second surface 21B of the first substrate 21 and the upper surface of the common source line 61 may form substantially the same plane.

The plurality of first interlayer insulating layers 33 and the plurality of first horizontal wiring layers 37 may be alternately stacked on the first surface 21F of the first substrate 21 and the lower surface of the common source line 61. The plurality of first interlayer insulating layers 33 and the plurality of first horizontal wiring layers 37 may extend in the first direction FD from the first cell area CAR1 into the connection area EXT. The plurality of connection pads RP may be disposed in the connection area EXT. Each of the plurality of connection pads RP may be connected to a distal end, in the connection area EXT, of a corresponding one among the plurality of first horizontal wiring layers 37. In an embodiment, each of the plurality of connection pads RP may contact the lower surface of a corresponding one among the plurality of first horizontal wiring layers 37. In the connection area EXT, the plurality of first interlayer insulating layers 33 and the plurality of first horizontal wiring layers 37 may form a stairway shape in the first direction FD. The first buried insulating layer 39 may be disposed in the connection area EXT. The first buried insulating layer 39 may cover the plurality of connection pads RP, the plurality of first horizontal wiring layers 37 and the plurality of first interlayer insulating layers 33, which form the stairway shape. The first buried insulating layer 39 may contact the side surfaces of the plurality of first horizontal wiring layers 37, the lower surfaces and side surfaces of the plurality of connection pads RP, and the side surfaces of the plurality of first interlayer insulating layers 33.

The plurality of second interlayer insulating layers 44 and the plurality of second horizontal wiring layers 48 may be alternately stacked on the first stack structure ST1. The plurality of second interlayer insulating layers 44 and the plurality of second horizontal wiring layers 48 may extend from the first cell area CAR1 into the connection area EXT in the first direction FD. Each of the plurality of connection pads RP may be connected to a distal end, in connection area EXT, of a corresponding one among the plurality of second horizontal wiring layers 48. In an embodiment, each of the plurality of connection pads RP may contact the lower surface of a corresponding one among the plurality of second horizontal wiring layers 48. The plurality of second interlayer insulating layers 44 and the plurality of second horizontal wiring layers 48 may form a stairway shape, extending in the first direction FD, in the connection area EXT. The second buried insulating layer 49 may be disposed in the connection area EXT. The second buried insulating layer 49 may cover the plurality of connection pads RP, the plurality of second horizontal wiring layers 48 and the plurality of second interlayer insulating layers 44, which form the stairway shape. The second buried insulating layer 49 may contact the side surfaces of the plurality of second horizontal wiring layers 48, the lower surfaces and side surfaces of the plurality of connection pads RP, and the side surfaces of the plurality of second interlayer insulating layers 44.

The plurality of channel structures 79 may be disposed in the first cell area CAR1. Each of the plurality of channel structures 79 may include a drain plug 78. Each of the plurality of channel structures 79 may completely pass through the first stack structure ST1 and the second stack structure ST2 in the second direction VD. Each of the plurality of channel structures 79 may be connected to the common source line 61 by passing through the plurality of second interlayer insulating layers 44, the plurality of second horizontal wiring layers 48, the plurality of first interlayer insulating layers 33 and the plurality of first horizontal wiring layers 37. In an embodiment, each of the plurality of channel structures 79 may extend into the common source line 61.

The plurality of first horizontal wiring layers 37 and the plurality of second horizontal wiring layers 48 may include a plurality of word lines, a plurality of select lines, and at least one gate induced drain leakage (GIDL) control line. In an embodiment, at least one among the plurality of first horizontal wiring layers 37, which is adjacent to the common source line 61, may correspond to a source select line. At least one among the plurality of second horizontal wiring layers 48, which is adjacent to the interface IF, may correspond to a drain select line. One among the plurality of first horizontal wiring layers 37, which is adjacent to the common source line 61, and/or one among the plurality of second horizontal wiring layers 48, which is adjacent to the interface IF, may correspond to the GIDL control line. A plurality of memory cells MC may be formed at intersections of the plurality of channel structures 79 and the plurality of word lines.

The plurality of contact plugs 81 and 82 and the plurality of through electrodes 91, 92 and 93 may be disposed in the connection area EXT. Each of the plurality of contact plugs 81 and 82 may be electrically connected to a corresponding one among the plurality of first horizontal wiring layers 37 and the plurality of second horizontal wiring layers 48. In an embodiment, each of the plurality of contact plugs 81 and 82 may directly contact a corresponding one among the plurality of connection pads RP by passing through the second buried insulating layer 49 and/or the first buried insulating layer 39. Each of the plurality of through electrodes 91, 92 and 93 may completely pass through the stack structure ST in the second direction VD.

The intermediate insulating layer 52 may cover the second stack structure ST2. The intermediate insulating layer 52 may be disposed between the second stack structure ST2 and the interface IF. The plurality of intermediate interconnections 53 and the plurality of upper pads 54 may be disposed in the intermediate insulating layer 52. The plurality of intermediate interconnections 53 may include a plurality of horizontal interconnections and a plurality of vertical interconnections. Each of the plurality of upper pads 54 may contact a corresponding one among the plurality of intermediate interconnections 53.

The upper isolation layer 23 may be disposed adjacent to the second surface 21B of the first substrate 21. The isolation insulating pattern 25 may pass through the first substrate 21 in the second direction VD. The upper insulating layer 27 may cover the second surface 21B of the first substrate 21, the upper isolation layer 23, the isolation insulating pattern 25, the plurality of upper interconnections 29, the common source line 61 and the plurality of upper transistors 63, 65 and 67. The plurality of upper interconnections 29 may include a plurality of horizontal interconnections and a plurality of vertical interconnections. Some among the plurality of upper interconnections 29 may directly contact the plurality of through electrodes 91, 92 and 93 by passing through the isolation insulating pattern 25 and the contact spacers 89.

The lower isolation layer 123 may be disposed adjacent to the first surface 121F of the second substrate 121. The lower insulating layer 125 may cover the first surface 121F of the second substrate 121, the lower isolation layer 123 and the plurality of lower transistors 151, 161 and 171. The plurality of lower interconnections 183 and the plurality of lower pads 184 may be disposed in the lower insulating layer 125. The plurality of lower interconnections 183 may include a plurality of horizontal interconnections and a plurality of vertical interconnections. Each of the plurality of lower pads 184 may contact a corresponding one among the plurality of lower interconnections 183.

The intermediate insulating layer 52 and the plurality of upper pads 54 may be bonded to the lower insulating layer 125 and the plurality of lower pads 184. The lower insulating layer 125 may directly contact the intermediate insulating layer 52, and each of the plurality of lower pads 184 may directly contact a corresponding one among the plurality of upper pads 54. The interface IF may be formed between the lower insulating layer 125 and the intermediate insulating layer 52 and between the plurality of lower pads 184 and the plurality of upper pads 54.

In an embodiment, one of the pair of source and drain areas SD of the first upper pass transistor 63 may be connected to a first contact plug 81 via corresponding some of the plurality of upper interconnections 29, a first through electrode 91 and corresponding some of the plurality of intermediate interconnections 53. The first upper pass transistor 63 may be electrically connected to a corresponding second horizontal wiring layers 48 from among the plurality of second horizontal wiring layers 48.

In an embodiment, one of the pair of source and drain areas SD of the first lower pass transistor 151 may be connected to a second contact plug 82 via corresponding some of the plurality of lower interconnections 183, a corresponding one among the plurality of lower pads 184, a corresponding one among the plurality of upper pads 54 and corresponding some of the plurality of intermediate interconnections 53. The first lower pass transistor 151 may be electrically connected to another corresponding second horizontal wiring layers 48 from among the plurality of second horizontal wiring layers 48.

The first lower pass transistor 151 may be included in a first pass transistor group. The first upper pass transistor 63 may be included in a second pass transistor group. The first upper pass transistor 63 and the first lower pass transistor 151 may be electrically connected to the first upper block switch transistor 67 and/or the first lower block switch transistor 171.

In an embodiment, one of the pair of source and drain areas SD of the first upper block switch transistor 67 may be connected to the upper end of a second through electrode 92 via corresponding some of the plurality of upper interconnections 29. One of the pair of source and drain areas SD of the first lower block switch transistor 171 may be connected to the lower end of the second through electrode 92 via corresponding some of the plurality of lower interconnections 183, a corresponding one of the plurality of lower pads 184, a corresponding one of the plurality of upper pads 54 and corresponding some of the plurality of intermediate interconnections 53. The upper end of the second through electrode 92 may be connected to the gate electrode GE of the first upper pass transistor 63 via corresponding some of the plurality of upper interconnections 29 and the first upper block switch transistor 67. The lower end of the second through electrode 92 may be connected to the gate electrode GE of the first lower pass transistor 151 via corresponding some of the plurality of intermediate interconnections 53, a corresponding one of the plurality of upper pads 54, a corresponding one of the plurality of lower pads 184, corresponding some of the plurality of lower interconnections 183 and the first lower block switch transistor 171. In an embodiment, one of the transistors selected between the first upper block switch transistor 67 and the first lower block switch transistor 171 may be omitted.

In an embodiment, one of the pair of source and drain areas SD of a first upper page buffer transistor 65 may be connected to the upper end of a third through electrode 93 via corresponding some of the plurality of upper interconnections 29. The lower end of the third through electrode 93 may be connected to the drain plug 78 of a corresponding one of the plurality of channel structures 79 via corresponding some of the plurality of intermediate interconnections 53. The first upper page buffer transistor 65 may be electrically connected to a corresponding one of the plurality of channel structures 79 via the third through electrode 93. One of the pair of source and drain areas SD of the first lower page buffer transistor 161 may be connected to a drain plug 78 corresponding to another from among the plurality of channel structures 79, via corresponding some of the plurality of lower interconnections 183, a corresponding one of the plurality of lower pads 184, a corresponding one of the plurality of upper pads 54 and corresponding some of the plurality of intermediate interconnections 53. The first lower page buffer transistor 161 may be electrically connected to a channel structure corresponding to another from among the plurality of channel structures 79.

According to embodiments of the technical spirit of the disclosed technology, due to the disposition and arrangement of the plurality of upper transistors 63, 65 and 67, the densities of the plurality of lower transistors 151, 161 and 171, the plurality of lower interconnections 183, the plurality of lower pads 184 and the plurality of upper pads 54 may be reduced.

Referring to FIG. 2, a channel structure 79 may include a channel layer 71, an information storage layer 76 and a core layer 77. The information storage layer 76 may include a tunnel layer 72, a charge trap layer 73 and a first blocking layer 74. The common source line 61 may directly contact the channel layer 71. The lower surface of the common source line 61 may contact the uppermost surface of the plurality of first interlayer insulating layers 33. The uppermost end of the information storage layer 76 may form substantially the same plane as the uppermost surface of the plurality of first interlayer insulating layers 33. The common source line 61 may contact the upper ends of the tunnel layer 72, the charge trap layer 73 and the first blocking layer 74. In an embodiment, the channel layer 71 may surround the side and upper surfaces of the core layer 77. The channel layer 71 and the core layer 77 may protrude in the second direction VD into the common source line 61. The uppermost end of the channel layer 71 may protrude to a level, in the second direction VD, higher than the lowermost end of the common source line 61 and the first surface 21F (see FIG. 1). The uppermost end of the core layer 77 may protrude to a level higher than the lowermost end of the common source line 61 and the first surface 21F (see FIG. 1).

The common source line 61 may include a conductive material such as metal, metal nitride, metal oxide, metal silicide, conductive carbon, polysilicon or a combination thereof. The common source line 61 may include a single layer or multiple layers. In an embodiment, the common source line 61 may include W, WN, Ru, Co, Pt, Ti, TiN, Ta, TaN, polysilicon or a combination thereof. For example, the common source line 61 may include polysilicon.

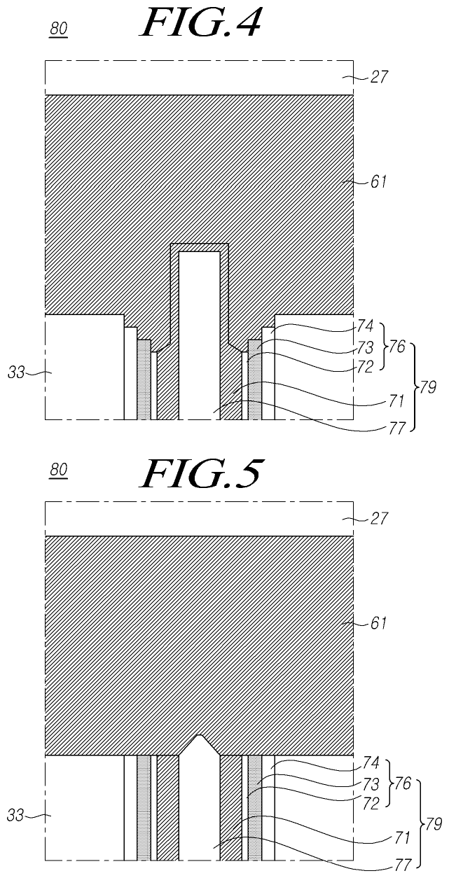

Referring to FIG. 3, the upper surface of the information storage layer 76 may be recessed to a level, in the second direction VD, lower than the uppermost surface of the plurality of first interlayer insulating layers 33. The uppermost end of the first blocking layer 74 may be formed at a level lower than the uppermost surface of the plurality of first interlayer insulating layers 33. The uppermost end of the charge trap layer 73 may be formed at a level lower than the uppermost end of the first blocking layer 74. The uppermost end of the tunnel layer 72 may be formed at a level lower than the uppermost end of the charge trap layer 73. The lowermost end of the common source line 61 common to the information storage layer 76 may extend to a level lower than the uppermost surface of the plurality of first interlayer insulating layers 33. The common source line 61 may contact the upper surface of the tunnel layer 72, the upper and side surfaces of the charge trap layer 73, the upper and side surfaces of the first blocking layer 74, and the upper and side surfaces of adjacent first interlayer insulating layers 33.

Referring to FIG. 4, the channel layer 71 may be partially recessed to be reduced in its thickness in the first direction FD. For example, the thickness of the channel layer 71 between the common source line 61 and the core layer 77 in the first direction FD may be smaller than the thickness of the channel layer 71 between the tunnel layer 72 and the core layer 77.

Referring to FIG. 5, portions of the channel layer 71 and the core layer 77 may be partially removed. For example, the common source line 61 may contact the upper end of the core layer 77. The upper ends of the information storage layer 76 and the channel layer 71 may form substantially the same plane as the uppermost surface of the plurality of first interlayer insulating layers 33. The common source line 61 may contact the upper end of the channel layer 71.

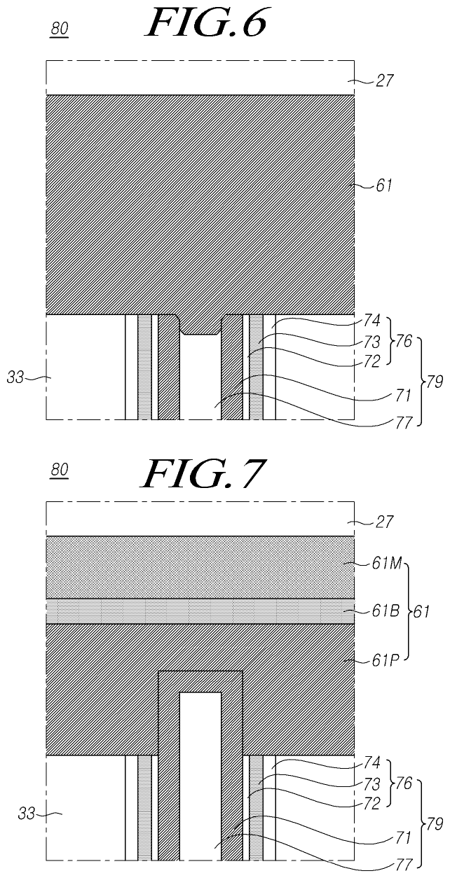

Referring to FIG. 6, the core layer 77 may be recessed to a level, in the second direction VD, lower than the uppermost surface of the plurality of first interlayer insulating layers 33. For example, the common source line 61 may extend downward in the second direction VD to contact the core layer 77. The lowermost end of the common source line 61 may extend to a level lower than the uppermost surface of the plurality of first interlayer insulating layers 33 and the uppermost end of the channel layer 71. The common source line 61 may contact the upper and side surfaces of the channel layer 71.

Referring to FIG. 7, the common source line 61 may include a single layer or multiple layers. In an embodiment, the common source line 61 may include a first layer 61P that contacts the channel layer 71, a second layer 61B on the first layer 61P, and a third layer 61M on the second layer 61B. The first layer 61P may include polysilicon. The second layer 61B may include metal silicide. The third layer 61M may include W, WN, Ru, Co, Pt, Ti, TiN, Ta, TaN or a combination thereof.

Referring to FIG. 8, the channel structure 79 may include the channel layer 71, the information storage layer 76 and the core layer 77. The information storage layer 76 may include the tunnel layer 72, the charge trap layer 73, a first blocking layer 74 and a second blocking layer 75. A memory cell MC may be provided at the intersection of the channel structure 79 and the first horizontal wiring layer 37.

The channel layer 71 may surround an outside of the core layer 77. The information storage layer 76 may surround an outside of the channel layer 71. The channel layer 71 may be interposed between the information storage layer 76 and the core layer 77. The tunnel layer 72 may surround the outside of the channel layer 71. The tunnel layer 72 may contact the channel layer 71. The charge trap layer 73 may surround an outside of the tunnel layer 72. The first blocking layer 74 may surround an outside of the charge trap layer 73. The second blocking layer 75 may be disposed between the first blocking layer 74 and the first horizontal wiring layer 37. The second blocking layer 75 may extend onto the upper and lower surfaces of the first horizontal wiring layer 37.

The channel structure 79 may include a drain plug 78 (see FIG. 1). The drain plug 78 (see FIG. 1) may contact the channel layer 71. In an embodiment, the second blocking layer 75 may be omitted.

Referring to FIG. 9, the channel structure 79 may include the channel layer 71, the information storage layer 76 and the core layer 77. The information storage layer 76 may include the tunnel layer 72, the charge trap layer 73 and the first blocking layer 74. The first blocking layer 74 may be interposed between the charge trap layer 73 and the first horizontal wiring layer 37. In an embodiment, the effective equivalent thickness of the first blocking layer 74 in the first direction FD may be larger than the effective equivalent thickness of the tunnel layer 72.

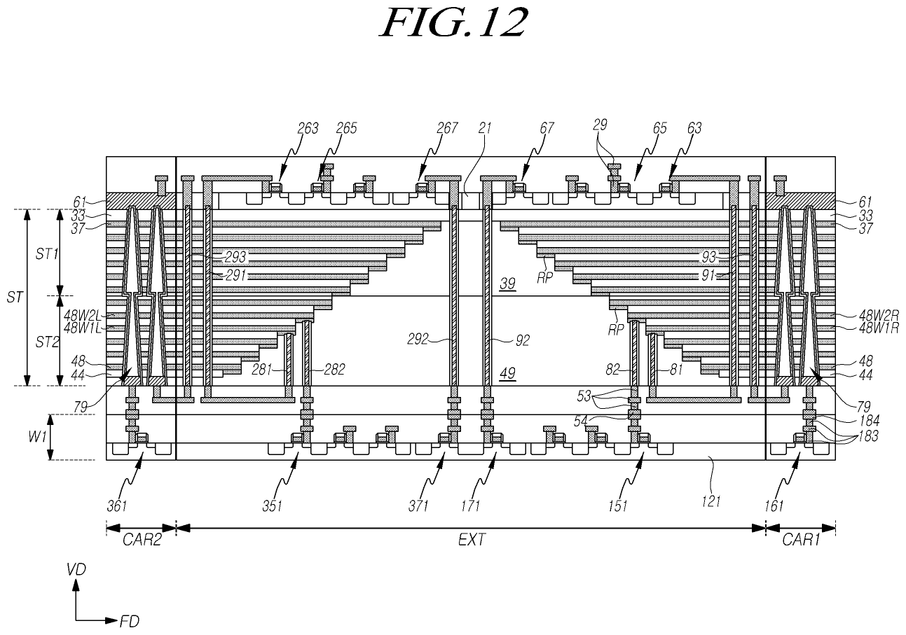

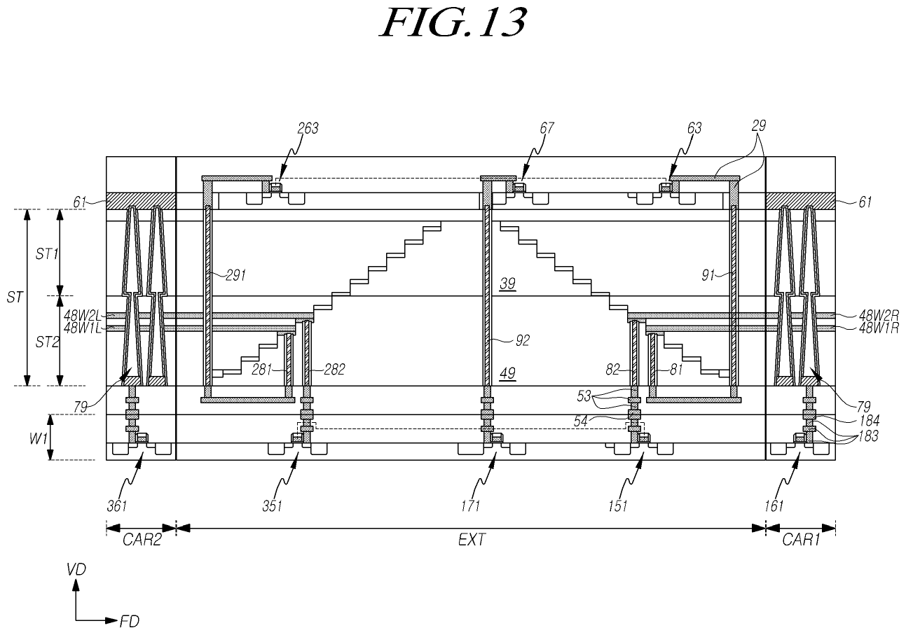

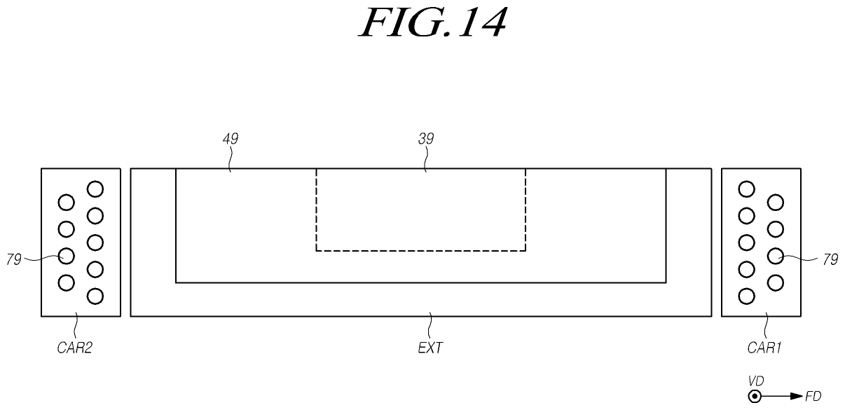

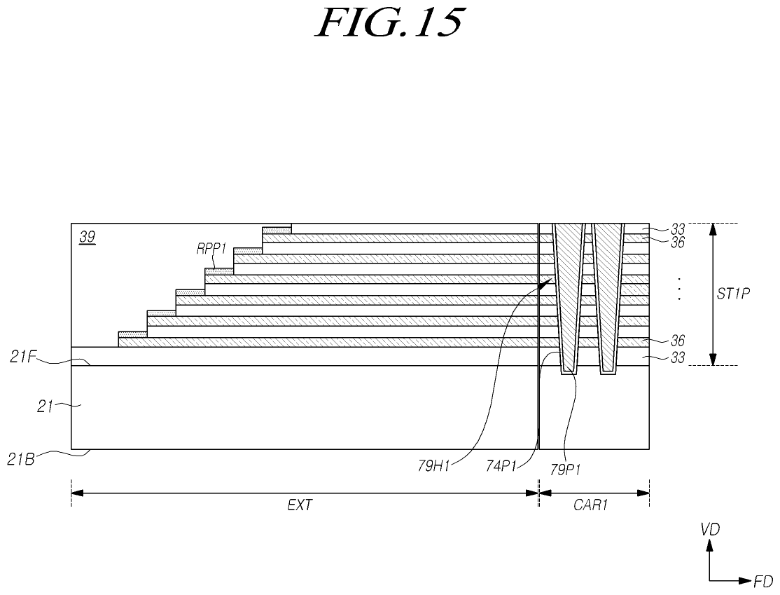

FIGS. 10 to 12 are cross-sectional views of semiconductor devices according to embodiments of the disclosure, and FIG. 13 is a partial view of a partial configuration of FIG. 12. FIG. 14 is a layout diagram of a semiconductor device according to an embodiment of the disclosure.

Referring to FIG. 10, in an embodiment, a first upper page buffer transistor (65 of FIG. 1) and a first upper block switch transistor (67 of FIG. 1) may be omitted. A first lower block switch transistor 171 may be electrically connected to a first upper pass transistor 63 and a first lower pass transistor 151.

Referring to FIG. 11, a first lower block switch transistor (171 of FIG. 1) may be omitted. A first upper block switch transistor 67 may be electrically connected to a first upper pass transistor 63 and a first lower pass transistor 151.

One of a pair of source and drain areas SD of the first upper pass transistor 63 may be connected to a first contact plug 81 via corresponding some of a plurality of upper interconnections 29, a first through electrode 91, corresponding some of a plurality of intermediate interconnections 53, one corresponding pair of a plurality of upper pads 54, one corresponding pair of a plurality of lower pads 184 and corresponding some of a plurality of lower interconnections 183.

One of a pair of source and drain areas SD of a first upper page buffer transistor 65 may be connected to a drain plug 78 of a corresponding one of a plurality of channel structures 79 via corresponding some of the plurality of upper interconnections 29, a third through electrode 93, corresponding some of the plurality of intermediate interconnections 53, one corresponding pair of the plurality of upper pads 54, one corresponding pair of the plurality of lower pads 184 and corresponding some of the plurality of lower interconnections 183.

Referring to FIG. 12, the semiconductor device based on the embodiment of the disclosed technology may include a shared slim structure. In an embodiment, a stack structure ST may include a plurality of cell areas CAR1 and CAR2 and a connection area EXT. The plurality of cell areas CAR1 and CAR2 may share the connection area EXT. For example, the connection area EXT may be disposed between the first cell area CAR1 and the second cell area CAR2. The connection area EXT may be referred to as a slim or a slim area. Each of the first cell area CAR1 and the second cell area CAR2 may include a plurality of channel structures 79.

A plurality of second horizontal wiring layers 48, 48W1R, 48W1L, 48W2R and 48W2L may include a first word line right portion 48W1R, a first word line left portion 48W1L, a second word line right portion 48W2R and a second word line left portion 48W2L. The first word line right portion 48W1R and the first word line left portion 48W1L may constitute a first word line, and the second word line right portion 48W2R and the second word line left portion 48W2L may constitute a second word line.

Each of the first and second word line right portions 48W1R and 48W2R may extend from the first cell area CAR1 to the connection area EXT in a first direction FD. Each of the first and second word line left portions 48W1L and 48W2L may extend from the second cell area CAR2 to the connection area EXT in the first direction FD. As illustrated in FIGS. 12 to 14, each of the first and second word line right portions 48W1R and 48W2R may be connected to a corresponding one of the first and second word line left portions 48W1L and 48W2L through the connection area EXT of the stack structure ST without a first buried insulating layer 39 and a second buried insulating layer 49. Each of the first and second word line right portions 48W1R and 48W2R may be disposed at substantially the same level, in the second direction VD, as a corresponding one of the first and second word line left portions 48W1L and 48W2L. For example, the first word line right portion 48W1R may be disposed at substantially the same level as the first word line left portion 48W1L. The first word line right portion 48W1R may be connected to the first word line left portion 48W1L through the connection area EXT of the stack structure ST which includes the plurality of first interlayer insulating layers 33, the plurality of first horizontal wiring layers 37, the plurality of second interlayer insulating layers 44 and the plurality of second horizontal wiring layers 48, but does not include a first buried insulating layer 39 and a second buried insulating layer 49.

The stack structure ST may include a plurality of contact plugs 81, 82, 281 and 282 and a plurality of through electrodes 91, 92, 93, 291, 292 and 293 which are disposed in the connection area EXT. Each of the plurality of contact plugs 81, 82, 281 and 282 may be electrically connected to a corresponding one of a plurality of first horizontal wiring layers 37 and a plurality of second horizontal wiring layers 48. In an embodiment, each of the plurality of contact plugs 81, 82, 281 and 282 may pass through a second buried insulating layer 49 and/or a first buried insulating layer 39 and thereby directly contact a corresponding one among a plurality of connection pads RP. Each of the plurality of through electrodes 91, 92, 93, 291, 292 and 293 may completely pass through the stack structure ST in a second direction VD.

A plurality of upper transistors 63, 65, 67, 263, 265 and 267, which are formed on or adjacent to a second surface (21B of FIG. 1) of a first substrate 21, may be provided. Each of the plurality of upper transistors 63, 65, 67, 263, 265 and 267 may be referred to as a backside transistor. The plurality of upper transistors 63, 65, 67, 263, 265 and 267 include a first upper pass transistor 63, a first upper page buffer transistor 65, a first upper block switch transistor 67, a second upper pass transistor 263, a second upper page buffer transistor 265 and a second upper block switch transistor 267. The plurality of upper transistors 63, 65, 67, 263, 265 and 267 may be aligned, in the second direction VD, at an upper part of the connection area EXT.

In an embodiment, a common source line 61 may be disposed at substantially the same horizontal level, in the second direction VD, as the first substrate 21. The first substrate 21 may be aligned at an upper part of the connection area EXT. The common source line 61 may be aligned at upper parts of the first cell area CAR1 and the second cell area CAR2. A first surface (21F of FIG. 1) of the first substrate 21 and the lower surface of the common source line 61 may form substantially the same plane. The second surface (21B of FIG. 1) of the first substrate 21 and the upper surface of the common source line 61 may form substantially the same plane.

A logic structure W1 may include a plurality of lower transistors 151, 161, 171, 351, 361 and 371. The plurality of lower transistors 151, 161, 171, 351, 361 and 371 may include a first lower pass transistor 151, a first lower page buffer transistor 161, a first lower block switch transistor 171, a second lower pass transistor 351, a second lower page buffer transistor 361 and a second lower block switch transistor 371. The plurality of lower transistors 151, 161, 171, 351, 361 and 371 may be disposed on or adjacent to a first surface (121F of FIG. 1) of a second substrate 121.

In an embodiment, the first upper pass transistor 63 may be connected to a first contact plug 81 via a first through electrode 91. The first upper pass transistor 63 may be electrically connected to the first word line right portion 48W1R via the first through electrode 91 and the first contact plug 81. The second upper pass transistor 263 may be connected to a third contact plug 281 via a fourth through electrode 291. The second upper pass transistor 263 may be electrically connected to the first word line left portion 48W1L via the fourth through electrode 291 and the third contact plug 281.

In an embodiment, the first low pass transistor 151 may be connected to a second contact plug 82. The first lower pass transistor 151 may be electrically connected to the second word line right portion 48W2R via the second contact plug 82. The second lower pass transistor 351 may be connected to a fourth contact plug 282. The second lower pass transistor 351 may be electrically connected to the second word line left portion 48W2L via the fourth contact plug 282.

The first and second lower pass transistors 151 and 351 may be included in a first pass transistor group. The first and second upper pass transistors 63 and 263 may be included in a second pass transistor group. The first and second upper pass transistors 63 and 263 and the first and second lower pass transistors 151 and 351 may be electrically connected to at least ones of the first and second upper block switch transistors 67 and 267 and the first and second lower block switch transistors 171 and 371. Some of the transistors selected among the first and second upper block switch transistors 67 and 267 and the first and second lower block switch transistors 171 and 371 may be omitted.

In an embodiment, the first upper block switch transistor 67 may be connected to the upper end of a second through electrode 92. The first lower block switch transistor 171 may be connected to the lower end of the second through electrode 92. The second upper block switch transistor 267 may be connected to the upper end of a fifth through electrode 292. The second lower block switch transistor 371 may be connected to the lower end of the fifth through electrode 292.

In an embodiment, the first upper page buffer transistor 65 may be connected to the upper end of a third through electrode 93. The first upper page buffer transistor 65 may be electrically connected to a corresponding one among the plurality of channel structures 79 in the first cell area CAR1 via the third through electrode 93. The first lower page buffer transistor 161 may be electrically connected to corresponding another among the plurality of channel structures 79 in the first cell area CAR1. The second upper page buffer transistor 265 may be connected to the upper end of a sixth through electrode 293. The second upper page buffer transistor 265 may be electrically connected to a corresponding one among the plurality of channel structures 79 in the second cell area CAR2 via the sixth through electrode 293. The second lower page buffer transistor 361 may be electrically connected to corresponding another among the plurality of channel structures 79 in the second cell area CAR2.

Referring to FIG. 13, in the first direction FD, the distance between the first contact plug 81 and the first cell area CAR1 may be substantially the same as the distance between the third contact plug 281 and the second cell area CAR2. The distance, in the first direction FD, between a selected channel structure 79 in the first cell area CAR1 and the first contact plug 81 may be substantially the same as the distance between a selected channel structure 79 in the second cell area CAR2 and the third contact plug 281. The distance, in the first direction FD, between the second contact plug 82 and the first cell area CAR1 may be substantially the same as the distance between the fourth contact plug 282 and the second cell area CAR2. The distance, in the first direction FD, between a selected channel structure 79 in the first cell area CAR1 and the second contact plug 82 may be substantially the same as the distance between a selected channel structure 79 in the second cell area CAR2 and the fourth contact plug 282.

The signal transfer paths of the first word line right portion 48W1R and the first word line left portion 48W1L may be formed to be the same. The wiring resistance deviation of the first word line right portion 48W1R and the first word line left portion 48W1L may be reduced. The signal transfer paths of the second word line right portion 48W2R and the second word line left portion 48W2L may be formed to be the same. The wiring resistance deviation of the second word line right portion 48W2R and the second word line left portion 48W2L may be reduced.

In an embodiment, the first upper block switch transistor 67 and/or the first lower block switch transistor 171 may be electrically connected to the first and second upper pass transistors 63 and 263 and the first and second lower pass transistors 151 and 351 via the second through electrode 92.

Referring to FIG. 14, a semiconductor device may include a shared slim structure. In an embodiment, each of the plurality of cell areas CAR1 and CAR2 may be disposed at a side of the connection area EXT. The plurality of cell areas CAR1 and CAR2 may share the connection area EXT. For example, the connection area EXT may be disposed between the first cell area CAR1 and the second cell area CAR2 in the first direction FD. The connection area EXT may be referred to as a slim or a slim area. Each of the first cell area CAR1 and the second cell area CAR2 may include the plurality of channel structures 79. A first buried insulating layer 39 and the second buried insulating layer 49 may be disposed in the connection area EXT.

As illustrated in FIGS. 12 to 14, each of the first and second word line right portions 48W1R and 48W2R may be connected to a corresponding one of the first and second word line left portions 48W1L and 48W2L through the connection area EXT. The plurality of first horizontal wiring layers 37 and the plurality of second horizontal wiring layers 48 in the first cell area CAR1 may be connected to the plurality of first horizontal wiring layers 37 and the plurality of second horizontal wiring layers 48 in the second cell area CAR2 through the connection area EXT.

FIGS. 15 to 27 are cross-sectional views illustrating a method for forming a semiconductor device according to an embodiment of the disclosure.

Referring to FIG. 15, a method for forming a semiconductor device may include forming a first preliminary stack structure ST1P on a first surface 21F of a first substrate 21. The first preliminary stack structure ST1P may include a plurality of first interlayer insulating layers 33, a plurality of first mold layers 36 and a first buried insulating layer 39.

The plurality of first interlayer insulating layers 33 and the plurality of first mold layers 36 may be alternately and repeatedly stacked. The plurality of first interlayer insulating layers 33 and the plurality of first mold layers 36 may be stacked in a second direction VD. In an embodiment, each of the lowermost layer and the uppermost layer of the first preliminary stack structure ST1P may be one of the plurality of first interlayer insulating layers 33. Each of the plurality of first mold layers 36 may extend in a first direction FD. Each of the plurality of first mold layers 36 may extend from a first cell area CAR1 to a connection area EXT. The plurality of first mold layers 36 may be formed to have a stairway shape in the connection area EXT. A plurality of first preliminary connection pads RPP1 may be formed in the connection area EXT.

Each of the plurality of first preliminary connection pads RPP1 may directly contact the upper surface of a corresponding one among the plurality of first mold layers 36. Each of the plurality of first preliminary connection pads RPP1 may be formed adjacent to the distal end of a corresponding one among the plurality of first mold layers 36. The first buried insulating layer 39 may be formed in the connection area EXT. The first buried insulating layer 39 may cover the plurality of first preliminary connection pads RPP1 and the plurality of first mold layers 36. The first buried insulating layer 39 may contact the upper and side surfaces of the plurality of first preliminary connection pads RPP1, the side surfaces of the plurality of first mold layers 36 and the side surfaces of the plurality of first interlayer insulating layers 33.

A plurality of lower channel holes 79H1, which pass through the first preliminary stack structure ST1P and extend into the first substrate 21, may be formed. A plurality of first preliminary channels 79P1 and a plurality of sacrificial spacers 74P1 may be formed in the plurality of lower channel holes 79H1. The plurality of sacrificial spacers 74P1 may be formed to surround the side surfaces and bottoms of the plurality of first preliminary channels 79P1. Each of the plurality of first preliminary channels 79P1 may extend in the second direction VD in the first cell area CAR1. Each of the plurality of first preliminary channels 79P1 may completely pass through the plurality of first interlayer insulating layers 33 and the plurality of first mold layers 36 and extend into the first substrate 21. The upper surfaces of the plurality of first preliminary channels 79P1, the plurality of sacrificial spacers 74P1, the first buried insulating layer 39 and the plurality of first interlayer insulating layers 33 may be exposed on substantially the same plane.

The first substrate 21 may include a semiconductor substrate such as a silicon wafer. The plurality of first interlayer insulating layers 33 may include at least two selected from the group consisting of Si, O, N, B, C and H. The plurality of first interlayer insulating layers 33 may include silicon oxide, silicon nitride, silicon oxynitride or a combination thereof. The plurality of first mold layers 36 may include a material that has an etch selectivity with respect to the plurality of first interlayer insulating layers 33.

The plurality of first preliminary connection pads RPP1 may include a material that has an etch selectivity with respect to the plurality of first mold layers 36 and the plurality of first interlayer insulating layers 33. In an embodiment, the plurality of first interlayer insulating layers 33 may include silicon oxide, the plurality of first mold layers 36 may include silicon nitride, and the plurality of first preliminary connection pads RPP1 may include polysilicon. In an embodiment, the plurality of first preliminary connection pads RPP1 may include the same material as the plurality of first mold layers 36. The first buried insulating layer 39 may include silicon oxide, silicon nitride, silicon oxynitride or a combination thereof. The first buried insulating layer 39 may include a material that has an etch selectivity with respect to the plurality of first preliminary connection pads RPP1 and the plurality of first mold layers 36. In an embodiment, the first buried insulating layer 39 may include silicon oxide.

The plurality of first preliminary channels 79P1 may include a material that has an etch selectivity with respect to the plurality of first mold layers 36 and the plurality of first interlayer insulating layers 33. In an embodiment, the plurality of first preliminary channels 79P1 may include polysilicon. The plurality of sacrificial spacers 74P1 may include a material that has an etch selectivity with respect to the plurality of first preliminary channels 79P1. The plurality of sacrificial spacers 74P1 may include an insulating material such as silicon oxide, silicon nitride, silicon oxynitride, metal oxide or a combination thereof. In an embodiment, the plurality of sacrificial spacers 74P1 may include silicon oxide.

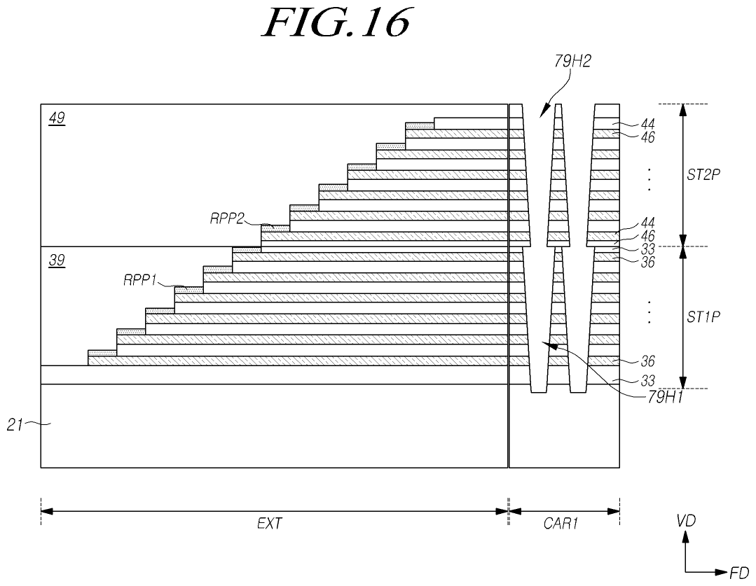

Referring to FIG. 16, a second preliminary stack structure ST2P may be formed on the first preliminary stack structure ST1P. The second preliminary stack structure ST2P may include a plurality of second interlayer insulating layers 44, a plurality of second mold layers 46 and a second buried insulating layer 49.

The plurality of second interlayer insulating layers 44 and the plurality of second mold layers 46 may be alternately and repeatedly stacked. The plurality of second interlayer insulating layers 44 and the plurality of second mold layers 46 may be stacked in the second direction VD. In an embodiment, the lowermost layer of the second preliminary stack structure ST2P may include a corresponding one among the plurality of second interlayer insulating layers 44. The lower surface of the second preliminary stack structure ST2P may directly contact the upper surface of the first preliminary stack structure ST1P. The uppermost layer of the second preliminary stack structure ST2P may include the second buried insulating layer 49. The second buried insulating layer 49 may cover the uppermost layer of the plurality of second interlayer insulating layers 44. Each of the plurality of second mold layers 46 may extend in the first direction FD. Each of the plurality of second mold layers 46 may extend from the first cell area CAR1 to the connection area EXT. The plurality of second mold layers 46 may be formed to have a stairway shape in the connection area EXT. A plurality of second preliminary connection pads RPP2 may be formed in the connection area EXT.

Each of the plurality of second preliminary connection pads RPP2 may directly contact the upper surface of a corresponding one among the plurality of second mold layers 46. Each of the plurality of second preliminary connection pads RPP2 may be formed adjacent to the distal end of a corresponding one among the plurality of second mold layers 46. The second buried insulating layer 49 may cover the plurality of second preliminary connection pads RPP2 and the plurality of second mold layers 46. The second buried insulating layer 49 may contact the upper and side surfaces of the plurality of second preliminary connection pads RPP2, the side surfaces of the plurality of second mold layers 46 and the side surfaces of the plurality of second interlayer insulating layers 44.

A plurality of upper channel holes 79H2, which pass through the second preliminary stack structure ST2P, may be formed. Each of the plurality of upper channel holes 79H2 may extend in the second direction VD in the first cell area CAR1. Each of the plurality of upper channel holes 79H2 may completely pass through the plurality of second interlayer insulating layers 44 and the plurality of second mold layers 46. Each of the plurality of upper channel holes 79H2 may be aligned with the upper portion of a corresponding one among the plurality of lower channel holes 79H1.

By removing the plurality of first preliminary channels 79P1 and the plurality of sacrificial spacers 74P1, the plurality of lower channel holes 79H1 may be exposed. Each of the plurality of lower channel holes 79H1 may communicate with the lower portion of a corresponding one among the plurality of upper channel holes 79H2 and may be aligned in a plan view. The plurality of first interlayer insulating layers 33, the plurality of first mold layers 36, the plurality of second interlayer insulating layers 44 and the plurality of second mold layers 46 may be exposed on the inner walls of the plurality of lower channel holes 79H1 and the plurality of upper channel holes 79H2.

The plurality of second interlayer insulating layers 44 may include the same material as the plurality of first interlayer insulating layers 33, the plurality of second mold layers 46 may include the same material as the plurality of first mold layers 36, and the plurality of second preliminary connection pads RPP2 may include the same material as the plurality of first preliminary connection pads RPP1. The second buried insulating layer 49 may include silicon oxide, silicon nitride, silicon oxynitride or a combination thereof. The second buried insulating layer 49 may include a material that has an etch selectivity with respect to the plurality of second preliminary connection pads RPP2 and the plurality of second mold layers 46. In an embodiment, the second buried insulating layer 49 may include silicon oxide.

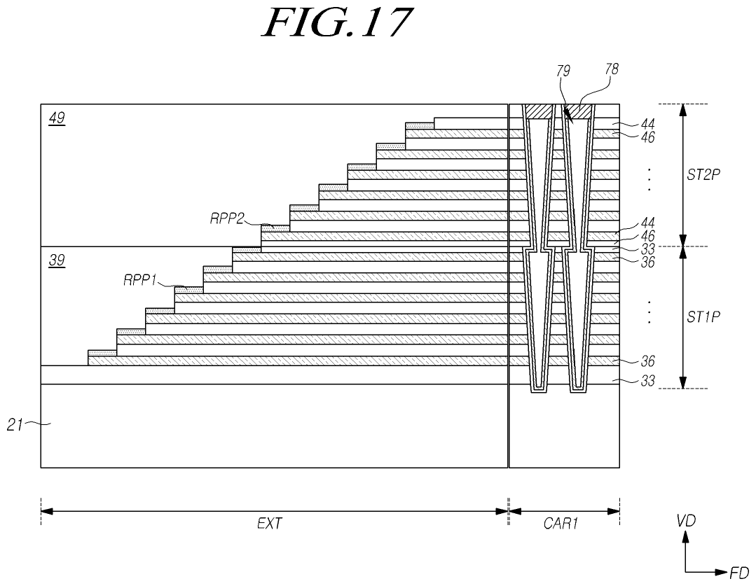

Referring to FIG. 17, a plurality of channel structures 79 may be formed in the plurality of upper channel holes 79H2 and the plurality of lower channel holes 79H1. In an embodiment, similar to the illustration of FIG. 9, each of the plurality of channel structures 79 may include a channel layer 71, an information storage layer 76 and a core layer 77. The information storage layer 76 may include a tunnel layer 72, a charge trap layer 73 and a first blocking layer 74. Each of the plurality of channel structures 79 may include a drain plug 78. The drain plug 78 may contact the channel layer 71. The upper ends of a plurality of drain plugs 78 may be exposed.

In an embodiment, each of the plurality of channel structures 79 may extend into the first substrate 21 by passing through the first preliminary stack structure ST1P and the second preliminary stack structure ST2P. The channel layer 71 may surround the outside of the core layer 77. The tunnel layer 72 may surround the outside of the channel layer 71. The charge trap layer 73 may surround the outside of the tunnel layer 72. The first blocking layer 74 may surround the outside of the charge trap layer 73.

The channel layer 71 may include a semiconductor material such as polysilicon, amorphous silicon, monocrystalline silicon or a combination thereof. The tunnel layer 72 may include silicon oxide. The charge trap layer 73 may include silicon nitride. The first blocking layer 74 may include silicon oxide, metal oxide, metal nitride or a combination thereof. The core layer 77 may include silicon oxide, silicon nitride, silicon oxynitride, polysilicon or a combination thereof.

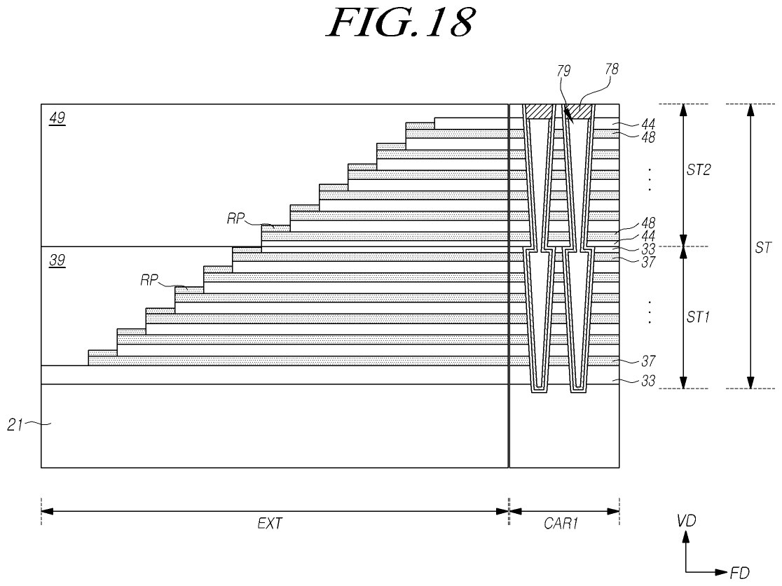

Referring to FIG. 18, the plurality of first mold layers 36, the plurality of second mold layers 46, the plurality of first preliminary connection pads RPP1 and the plurality of second preliminary connection pads RPP2 may be removed, and a plurality of first horizontal wiring layers 37, a plurality of second horizontal wiring layers 48 and a plurality of connection pads RP may be formed. The plurality of first interlayer insulating layers 33, the plurality of first horizontal wiring layers 37, the plurality of connection pads RP and the first buried insulating layer 39 may constitute a first stack structure ST1. The plurality of second interlayer insulating layers 44, the plurality of second horizontal wiring layers 48, the plurality of connection pads RP and the second buried insulating layer 49 may constitute a second stack structure ST2. The first stack structure ST1 and the second stack structure ST2 may constitute a stack structure ST.

The plurality of first horizontal wiring layers 37, the plurality of second horizontal wiring layers 48 and the plurality of connection pads RP may include a conductive material such as metal, metal nitride, metal oxide, metal silicide, conductive carbon, polysilicon or a combination thereof. Each of the plurality of first horizontal wiring layers 37, the plurality of second horizontal wiring layers 48 and the plurality of connection pads RP may include a single layer or multiple layers. In an embodiment, the plurality of first horizontal wiring layers 37, the plurality of second horizontal wiring layers 48 and the plurality of connection pads RP may include W, WN, Ru, Co, Pt, Ti, TiN, Ta, TaN or a combination thereof. Each of the plurality of first horizontal wiring layers 37, the plurality of second horizontal wiring layers 48 and the plurality of connection pads RP may include a conductive pattern and a barrier layer that surrounds the outside of the conductive pattern.

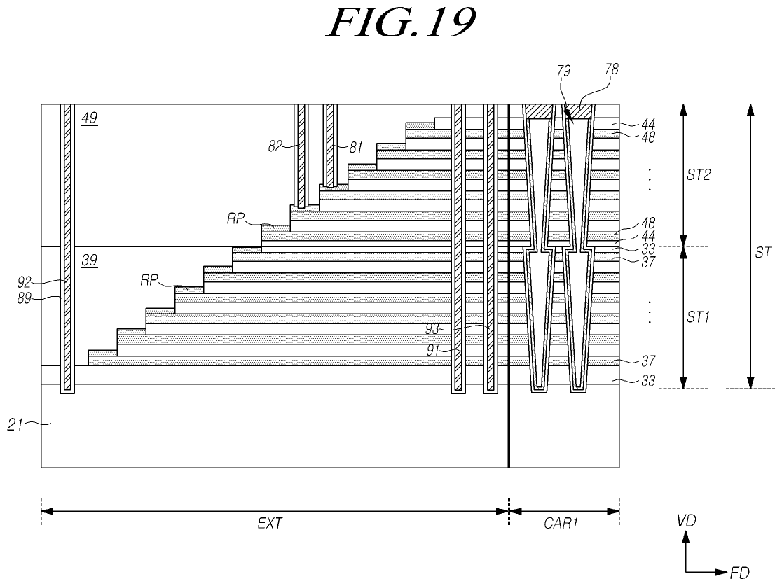

Referring to FIG. 19, a plurality of contact plugs 81 and 82 and a plurality of through electrodes 91, 92 and 93, which extend in the second direction VD, may be formed in the stack structure ST. Each of the plurality of contact plugs 81 and 82 and the plurality of through electrodes 91, 92 and 93 may be surrounded by a contact spacer 89. The plurality of contact plugs 81 and 82 and the plurality of through electrodes 91, 92 and 93 may be formed in the connection area EXT.

In an embodiment, each of the plurality of contact plugs 81 and 82 may directly contact a corresponding one among the plurality of connection pads RP by passing through the second buried insulating layer 49. Each of the plurality of contact plugs 81 and 82 may be electrically connected to a corresponding one among the plurality of second horizontal wiring layers 48 via a corresponding one among the plurality of connection pads RP.

In an embodiment, each of the plurality of through electrodes 91, 92 and 93 may extend into the first substrate 21 by completely passing through the stack structure ST. Each of the first and third through electrodes 91 and 93 may completely pass through the plurality of second interlayer insulating layers 44, the plurality of second horizontal wiring layers 48, the plurality of first interlayer insulating layers 33 and the plurality of first horizontal wiring layers 37. The second through electrode 92 may completely pass through the second buried insulating layer 49 and the first buried insulating layer 39.

Each of the plurality of contact plugs 81 and 82 and the plurality of through electrodes 91, 92 and 93 may include a conductive material such as metal, metal nitride, metal oxide, conductive carbon, polysilicon or a combination thereof. Each of the plurality of contact plugs 81 and 82 and the plurality of through electrodes 91, 92 and 93 may include a single layer or multiple layers. In an embodiment, each of the plurality of contact plugs 81 and 82 and the plurality of through electrodes 91, 92 and 93 may include W, WN, Ru, Co, Pt, Ti, TiN, Ta, TaN or a combination thereof. Each of the plurality of contact plugs 81 and 82 and the plurality of through electrodes 91, 92 and 93 may include a conductive pattern and a barrier layer that surrounds the outside of the conductive pattern. The contact spacer 89 may include an insulating material such as silicon oxide, silicon nitride, silicon oxynitride or a combination thereof.

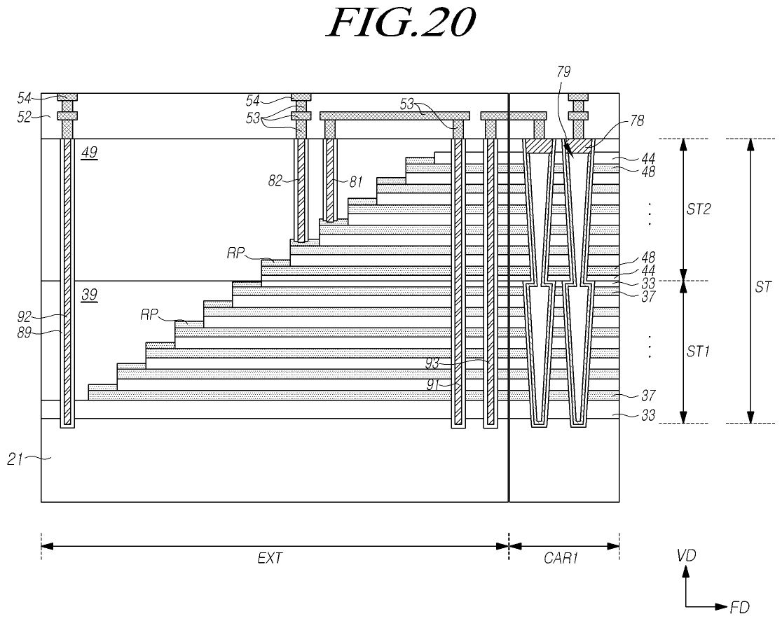

Referring to FIG. 20, an intermediate insulating layer 52 may be formed on the second stack structure ST2. A plurality of intermediate interconnections 53 and a plurality of upper pads 54 may be formed in the intermediate insulating layer 52. Forming the intermediate insulating layer 52 and the plurality of upper pads 54 may include a plurality of thin film forming processes and planarization processes. In an embodiment, the planarization process for forming the intermediate insulating layer 52 and the plurality of upper pads 54 may include a chemical mechanical polishing (CMP) process, an etch-back process or a combination thereof. The upper surfaces of the intermediate insulating layer 52 and the plurality of upper pads 54 may be exposed on substantially the same plane. The uppermost surface of the intermediate insulating layer 52 may include silicon oxide. The uppermost surfaces of the plurality of upper pads 54 may include Cu.

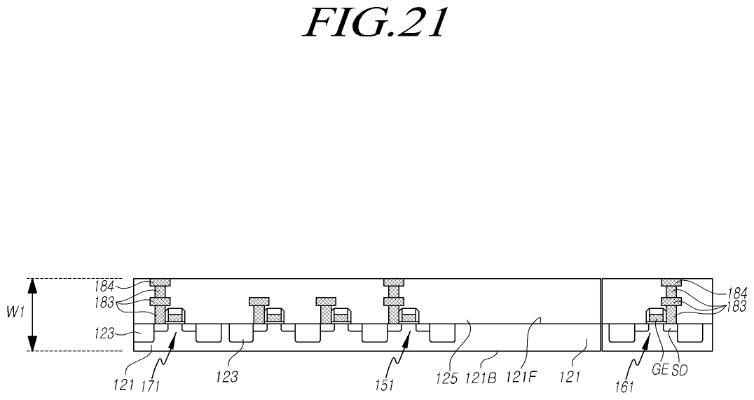

Referring to FIG. 21, on a second substrate 121, a lower isolation layer 123, a lower insulating layer 125, a plurality of lower transistors 151, 161 and 171, a plurality of lower interconnections 183 and a plurality of lower pads 184 may be formed. Forming the lower insulating layer 125 and the plurality of lower pads 184 may include a plurality of thin film forming processes and planarization processes. In an embodiment, the planarization process for forming the lower insulating layer 125 and the plurality of lower pads 184 may include a chemical mechanical polishing (CMP) process, an etch-back process or a combination thereof. The upper surfaces of the lower insulating layer 125 and the plurality of lower pads 184 may be exposed on substantially the same plane. The second substrate 121, the lower isolation layer 123, the lower insulating layer 125, the plurality of lower transistors 151, 161 and 171, the plurality of lower interconnections 183 and the plurality of lower pads 184 may constitute a logic structure W1.

The second substrate 121 may include a first surface 121F and a second surface 121B, which face opposite each other. In an embodiment, the lower isolation layer 123, the lower insulating layer 125, the plurality of lower transistors 151, 161 and 171, the plurality of lower interconnections 183 and the plurality of lower pads 184 may be formed on the first surface 121F of the second substrate 121. The second substrate 121 may include a semiconductor substrate such as a silicon wafer. The lower isolation layer 123 may be formed in the second substrate 121 using a shallow trench isolation (STI) technique.

Each of the plurality of lower transistors 151, 161 and 171 may include a gate electrode GE and a pair of source and drain areas SD. The lower insulating layer 125 may cover the lower isolation layer 123, the plurality of lower transistors 151, 161 and 171, the plurality of lower interconnections 183 and the plurality of lower pads 184. The plurality of lower interconnections 183 may include a plurality of horizontal interconnections and a plurality of vertical interconnections. Each of the plurality of lower interconnections 183 may be electrically connected to a corresponding one of the pair of source and drain areas SD of a corresponding one among the plurality of lower transistors 151, 161 and 171. Each of the plurality of lower pads 184 may contact a corresponding one among the plurality of lower interconnections 183. In an embodiment, the uppermost surface of the lower insulating layer 125 may include silicon oxide. The uppermost surfaces of the plurality of lower pads 184 may include Cu.

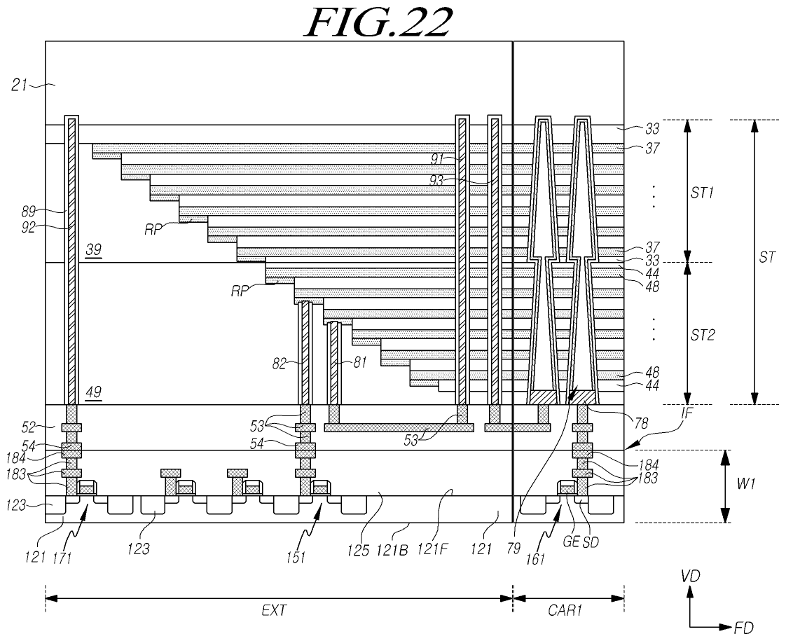

Referring to FIG. 22, the stack structure ST may be bonded onto the logic structure W1. An interface IF may be formed between the logic structure W1 and the stack structure ST. The intermediate insulating layer 52 and the plurality of upper pads 54 may be bonded to the lower insulating layer 125 and the plurality of lower pads 184. The interface IF may be formed between the lower insulating layer 125 and the intermediate insulating layer 52 and between the plurality of lower pads 184 and the plurality of upper pads 54. The intermediate insulating layer 52 may directly contact the lower insulating layer 125, and each of the plurality of upper pads 54 may directly contact a corresponding one among the plurality of lower pads 184.

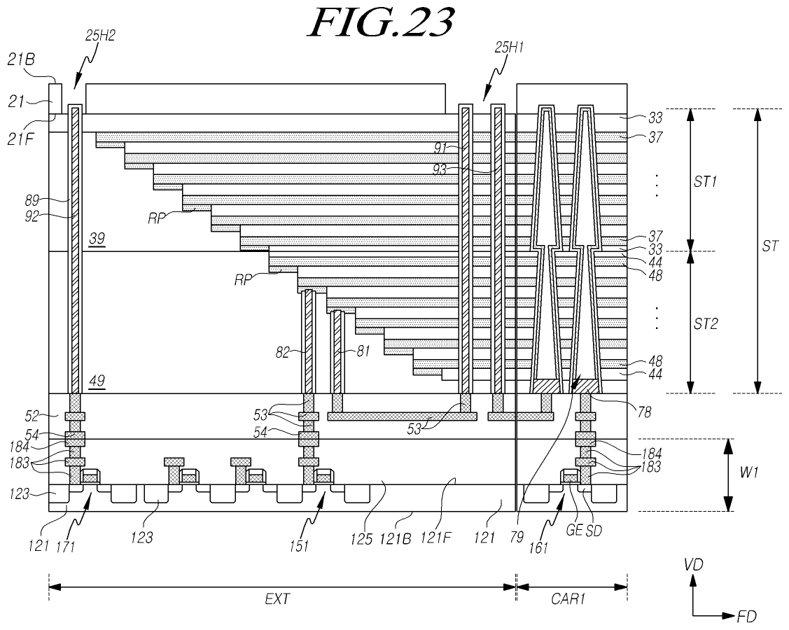

Referring to FIG. 23, by partially removing the first substrate 21, the thickness of the first substrate 21 may be reduced. Partially removing the first substrate 21 may include a backgrinding process. In an embodiment, the thickness of the first substrate 21 may be 5 μm to 50 μm. The first substrate 21 may include the first surface 21F and a second surface 21B, which face opposite each other. By patterning the first substrate 21, a plurality of openings 25H1 and 25H2 may be formed. Portions of the contact spacers 89 and one of the plurality of first interlayer insulating layers 33 may be exposed in the plurality of openings 25H1 and 25H2. The plurality of through electrodes 91, 92 and 93 may protrude in the second direction VD from the upper surface of the exposed first interlayer insulating layer 33 and into the plurality of openings 25H1 and 25H2, respectively.

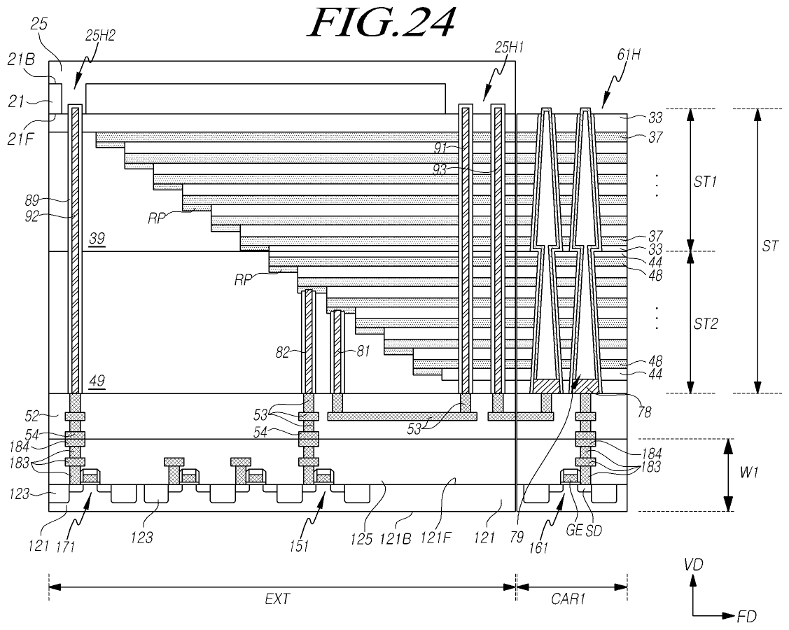

Referring to FIG. 24, an isolation insulating pattern 25, which fills the plurality of openings 25H1 and 25H2 and covers the second surface 21B of the first substrate 21, may be formed. By patterning the isolation insulating pattern 25 and the first substrate 21, a source opening 61H, which exposes the plurality of channel structures 79, may be formed. In an embodiment, the source opening 61H may be aligned at an upper part of the first cell area CAR1. A channel layer (71 of FIG. 2) may be exposed in the source opening 61H. The isolation insulating pattern 25 may include an insulating material such as silicon oxide, silicon nitride, silicon oxynitride or a combination thereof.

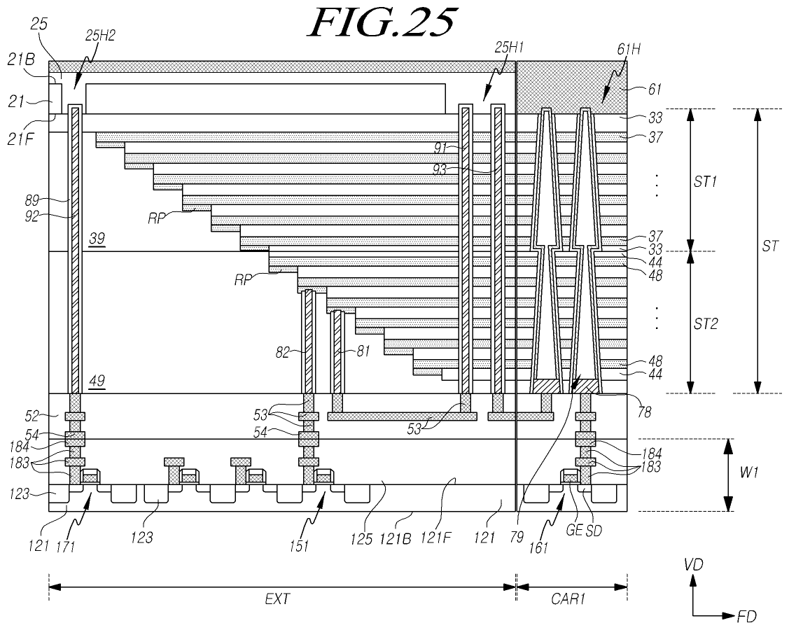

Referring to FIG. 25, a common source line 61, which fills the source opening 61H and covers the isolation insulating pattern 25, may be formed. The common source line 61 may directly contact the channel layer (71 of FIG. 2). The common source line 61 may include a conductive material such as metal, metal nitride, metal oxide, metal silicide, conductive carbon, polysilicon or a combination thereof. The common source line 61 may include a single layer or multiple layers. In an embodiment, the common source line 61 may include W, WN, Ru, Co, Pt, Ti, TiN, Ta, TaN, polysilicon or a combination thereof.

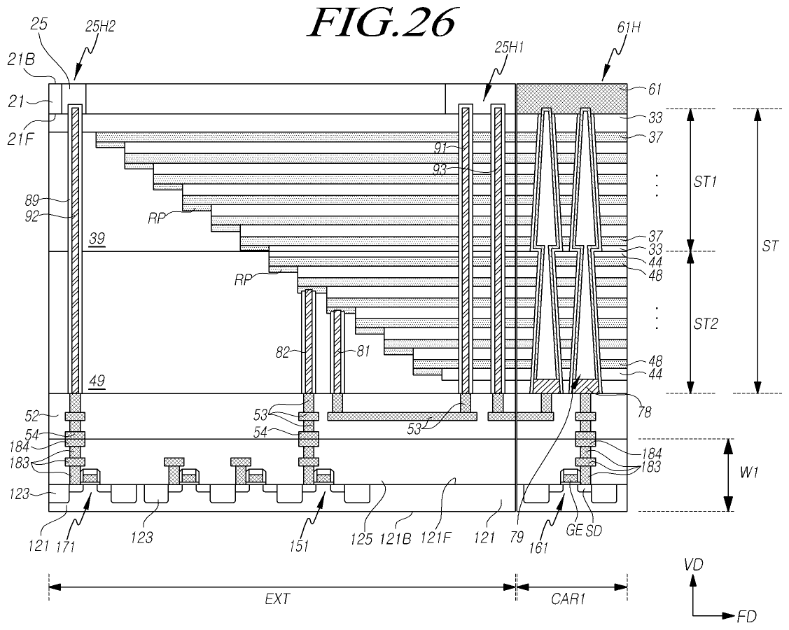

Referring to FIG. 26, by partially removing the common source line 61 and the isolation insulating pattern 25, the second surface 21B of the first substrate 21 may be exposed. Partially removing the common source line 61 and the isolation insulating pattern 25 may include a planarization process such as a chemical mechanical polishing (CMP) process, an etch-back process or a combination thereof. The common source line 61 may be preserved in the source opening 61H, and the isolation insulating pattern 25 may be preserved in the plurality of openings 25H1 and 25H2. The second surface 21B of the first substrate 21 and the upper surfaces of the common source line 61 and the isolation insulating pattern 25 may be exposed on substantially the same plane. The first surface 21F of the 20) first substrate 21 and the lower surfaces of the common source line 61 and the isolation insulating pattern 25 may form substantially the same plane. The common source line 61 and the plurality of channel structures 79 may include various shapes similar to those described above with reference to FIGS. 2 to 7. In an embodiment, the common source line 61 may be aligned at the upper part of the first cell area CAR1. The first substrate 21 may be remain at an upper part of the connection area EXT.

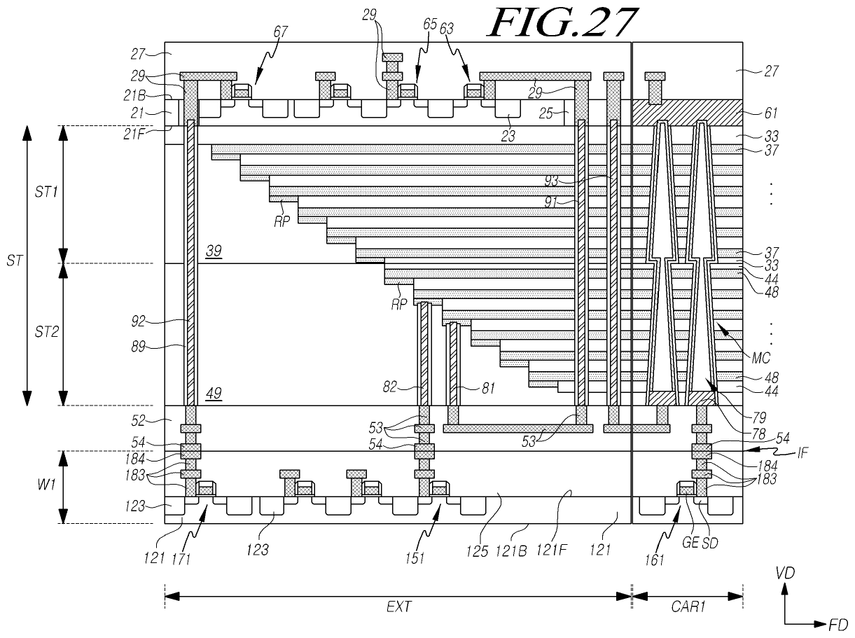

Referring to FIG. 27, an upper isolation layer 23, an upper insulating layer 27, a plurality of upper interconnections 29 and a plurality of upper transistors 63, 65 and 67 may be formed on the first substrate 21. The upper isolation layer 23 and the plurality of upper transistors 63, 65 and 67 may be formed adjacent to the second surface 21B of the first substrate 21. The upper insulating layer 27 may cover the second surface 21B of the first substrate 21, the upper isolation layer 23, the isolation insulating pattern 25, the plurality of upper interconnections 29, the common source line 61 and the plurality of upper transistors 63, 65 and 67.

The upper isolation layer 23 may be formed in the first substrate 21 using a shallow trench isolation (STI) technique. Each of the plurality of upper transistors 63, 65 and 67 may include a gate electrode GE and a pair of source and drain areas SD. Each of the pair of source and drain areas SD may be formed by implanting P-type or N-type impurity ions into the first substrate 21. Some among the plurality of upper interconnections 29 may contact the plurality of through electrodes 91, 92 and 93 by passing through the isolation insulating pattern 25 and the contact spacers 89. Some among the plurality of upper interconnections 29 may contact the pair of source and drain areas SD.

Each of the upper isolation layer 23 and the upper insulating layer 27 may include an insulating material such as silicon oxide, silicon nitride, silicon oxynitride or a combination thereof. Each of the gate electrode GE and the plurality of upper interconnections 29 may include a conductive material such as metal, metal nitride, metal oxide, metal silicide, conductive carbon, polysilicon or a combination thereof. Each of the gate electrode GE and the plurality of upper interconnections 29 may include a single layer or multiple layers. In an embodiment, each of the gate electrode GE and the plurality of upper interconnections 29 may include W, WN, Ru, Co, Pt, Ti, TiN, Ta, TaN or a combination thereof.

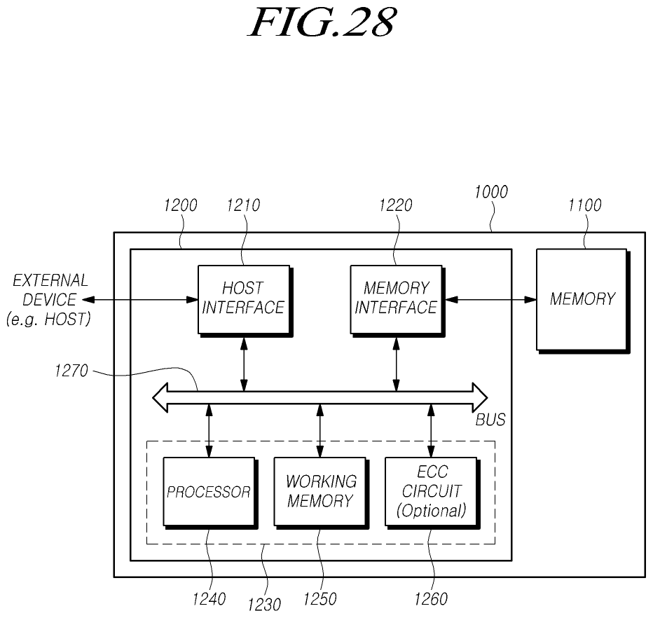

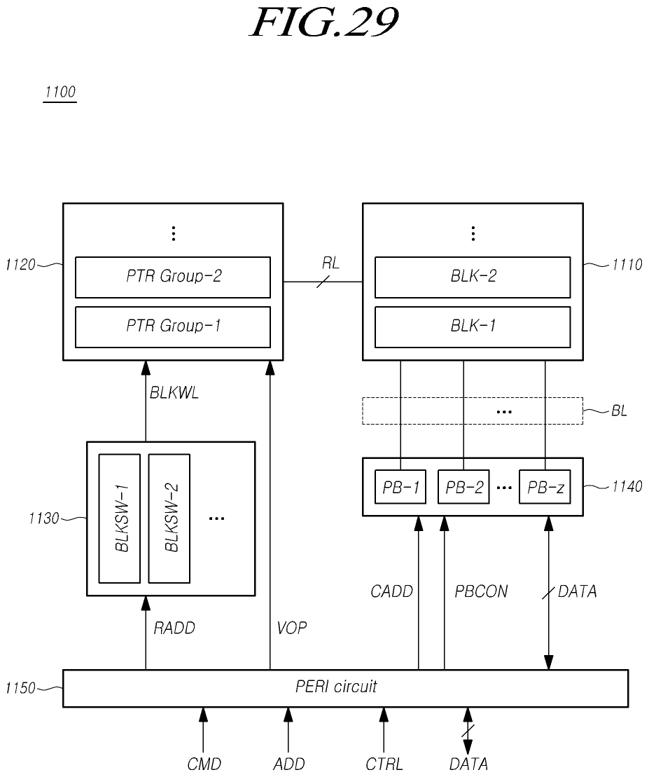

FIG. 28 is a schematic configuration diagram of a storage device according to an embodiment of the disclosure, and FIG. 29 is a block diagram schematically illustrating a memory of FIG. 28.

Referring to FIG. 28, a storage device 1000 may include a memory 1100 that stores data and a controller 1200 that controls the memory 1100. The memory 1100 may include a plurality of memory blocks, and may operate in response to the control of the controller 1200. In an embodiment, operations of the memory 1100 may include a read operation, a program operation (also referred to as a write operation) and an erase operation. The memory 1100 may include a memory cell array having a plurality of memory cells that store data. The memory cell array may be located in the memory blocks.

The memory 1100 may include a nonvolatile memory, a pseudo nonvolatile memory, a volatile memory, or a combination thereof. In an embodiment, the memory 1100 may include a NAND flash memory, a NOR flash memory, a resistive random access memory (RRAM), a phase-change random access memory (PRAM), a magnetoresistive random access memory (MRAM), a spin transfer torque (STT) MRAM, a spin-orbit torque (SOT) MRAM, a ferroelectric random access memory (FRAM), a three-dimensional crosspoint (3D X-point) memory, a dynamic random access memory (DRAM), a graphics double data rate (GDDR) synchronous DRAM (SDRAM), a Rambus DRAM (RDRAM), a high bandwidth memory (HBM), a static random access memory (SRAM), or a combination thereof.

The memory 1100 may receive a command and an address from the controller 1200 and may access an area that is selected by the address in the memory cell array. In an embodiment, the memory 1100 may perform an operation indicated by the command, on the area selected by the address.

The controller 1200 may control write (program), read, erase and background operations for the memory 1100. The background operation may include garbage collection (GC), wear leveling (WL), read reclaim (RR), bad block management (BBM), or a combination thereof. The controller 1200 may control the operation of the memory 1100 according to a request from a device (e.g., a host) located outside the storage device 1000. In an embodiment, the controller 1200 may control the operation of the memory 1100 regardless of a request of the host.

The host may include a computer, a smartphone, a navigation, a black box, a digital camera, a smart television, a digital video recorder, a storage configuring a data center, one of various electronic devices configuring a home network, one of various electronic devices configuring a computer network, one of various electronic devices configuring a telematics network, an RFID (radio frequency identification) device, a mobility device (e.g., a vehicle, a robot or a drone), or a combination thereof.

In an embodiment, the controller 1200 may include a host interface 1210, a memory interface 1220 and a control circuit 1230. The host interface 1210 may provide an interface for communication with the host. When receiving a command from the host, the control circuit 1230 may receive the command through the host interface 1210, and may perform an operation of processing the received command. The memory interface 1220 may be coupled with the memory 1100 to provide an interface for communication with the memory 1100. The memory interface 1220 may be configured to provide an interface between the memory 1100 and the controller 1200 in response to the control of the control circuit 1230.

The control circuit 1230 performs the general control operation of the controller 1200 to control the operation of the memory 1100. In an embodiment, the control circuit 1230 may include a processor 1240, a working memory 1250 and an error detection and correction circuit (ECC circuit) 1260. The processor 1240 may control general operations of the controller 1200, and may perform a logic calculation. The processor 1240 may communicate with the host through the host interface 1210, and may communicate with the memory 1100 through the memory interface 1220.

The working memory 1250 may store firmware, a program code, a command or data necessary to drive the controller 1200. The working memory 1250 may include a volatile memory such as a static RAM (SRAM), a dynamic RAM (DRAM), a synchronous DRAM (SDRAM), or a combination thereof.

The error detection and correction circuit 1260 may detect an error bit of target data and correct the detected error bit, by using an error correction code. The target data may be data stored in the working memory 1250, data read from the memory 1100, or a combination thereof.

A bus 1270 may be configured to provide channels among the components 1210, 1220, 1240, 1250 and 1260 of the controller 1200. The bus 1270 may include a control bus for transferring various control signals, commands and the likes, a data bus for transferring various data, and so forth.

In an embodiment, some components among the components 1210, 1220, 1240, 1250 and 1260 of the controller 1200 may be omitted, or some components among the components 1210, 1220, 1240, 1250 and 1260 of the controller 1200 may be incorporated into one component. In addition to the above-described components 1210, 1220, 1240, 1250 and 1260, one or more other components may be added to the controller 1200.

Referring to FIG. 29, the memory 1100 may include a memory cell array 1110, a pass transistor circuit 1120, a block selection circuit 1130, a page buffer circuit 1140 and a peripheral circuit (PERI circuit) 1150. The memory cell array 1110 may be coupled to the pass transistor circuit 1120 through a plurality of row lines RL, and may be coupled to the page buffer circuit 1140 through a plurality of bit lines BL. The plurality of row lines RL may include a plurality of word lines and a plurality of select lines. The plurality of select lines may include at least one source select line and at least one drain select line. In an embodiment, the plurality of row lines RL may include at least one gate induced drain leakage (GIDL) control line.

The memory cell array 1100 may include a plurality of memory blocks BLK-1, BLK-2, . . . . In an embodiment, each of the plurality of memory blocks BLK-1, BLK-2, . . . may be a basic unit of an erase operation.

The pass transistor circuit 1120 may transfer an operating voltage VOP, from the peripheral circuit 1150, to the plurality of row lines RL of a memory block selected among the plurality of memory blocks BLK-1, BLK-2, . . . of the memory cell array 1110 in response to a block selection signal BLKWL from the block selection circuit 1130. The pass transistor circuit 1120 may include a plurality of pass transistor groups PTR Group-1, PTR Group-2, . . . corresponding to the plurality of memory blocks BLK-1, BLK-2, . . . .

The pass transistor circuit 1120 may ground the plurality of select lines of a memory block selected from among the plurality of memory blocks BLK-1, BLK-2, . . . , in response to a discharge enable signal.

The block selection circuit 1130 may generate the block selection signal BLKWL in response to a row address signal RADD from the peripheral circuit 1150, and may provide the generated block selection signal BLKWL to the pass transistor circuit 1120. The pass transistor circuit 1120 and the block selection circuit 1130 may constitute a row decoder. The row decoder may be referred to as an X decoder or an address decoder. The block selection circuit 1130 may include a plurality of block switches BLKSW-1, BLKSW-2, . . . .

The page buffer circuit 1140 may be coupled to the memory cell array 1110 through the plurality of bit lines BL. The page buffer circuit 1140 may receive a page buffer control signal PBCON from the peripheral circuit 1150, and may transmit and receive data signals DATA to and from the peripheral circuit 1150.

The page buffer circuit 1140 may control the plurality of bit lines BL, which are coupled to the memory cell array 1110, in response to the page buffer control signal PBCON. For example, the page buffer circuit 1140 may detect data, stored in the memory cells of the memory cell array 1110, by sensing the signals of the plurality of bit lines BL of the memory cell array 1100 in response to the page buffer control signal PBCON, and may transmit data signals DATA to the peripheral circuit 1150 according to the detected data. The page buffer circuit 1140 may apply signals to the plurality of bit lines BL on the basis of data signals DATA received from the peripheral circuit 1150, in response to the page buffer control signal PBCON, and may write data to the memory cells of the memory cell array 1110. The page buffer circuit 1140 may write data to or read data from memory cells that are coupled to a word line activated by the row decoder. The page buffer circuit 1140 may include a plurality of page buffers PB-1, PB-2, . . . , PB-z.

The peripheral circuit 1150 may receive a command signal CMD, an address signal ADD and a control signal CTRL from a device outside the memory 1100, for example, a controller, and may transmit and receive data DATA to and from the device outside the memory 1100.

The peripheral circuit 1150 may output signals for writing data to the memory cell array 1110 or reading data from the memory cell array 1110, for example, the row address signal RADD, a column address signal CADD, the page buffer control signal PBCON and so forth, on the basis of the command signal CMD, the address signal ADD and the control signal CTRL. The peripheral circuit 1150 may generate various voltages including the operating voltage VOP, which are required in the memory 1100. For example, the peripheral circuit 1150 may generate program voltages, pass voltages, read voltages and erase voltages of various levels.

In an embodiment, the memory cell array 1100 may include a first memory block BLK-1. The pass transistor circuit 1120 may include first and second pass transistor groups PTR Group-1 and PTR Group-2 corresponding to the first memory block BLK-1. The block selection circuit 1130 may include a first block switch BLKSW-1.

In an embodiment, the first pass transistor group PTR Group-1 and the second pass transistor group PTR Group-2 may be coupled to the first memory block BLK-1 via the plurality of row lines RL. The first pass transistor group PTR Group-1 and the second pass transistor group PTR Group-2 may be selected in response to the block selection signal BLKWL from the block selection circuit 1130. The first pass transistor group PTR Group-1 and the second pass transistor group PTR Group-2 may transfer the operating voltage VOP from the peripheral circuit 1150, to the plurality of row lines RL of the first memory block BLK-1.

Referring again to FIGS. 1 and 29, in an embodiment, the first memory block BLK-1 may include the plurality of first horizontal wiring layers 37, the plurality of second horizontal wiring layers 48 and the plurality of channel structures 79. The plurality of memory cells MC may be disposed at the intersections of the plurality of channel structures 79 and the plurality of first horizontal wiring layers 37 and the intersections of the plurality of channel structures 79 and the plurality of second horizontal wiring layers 48.

At least a part of the pass transistor circuit 1120, the block selection circuit 1130, the page buffer circuit 1140 and the peripheral circuit 1150 may be disposed in a distributed manner inside the logic structure W1 and adjacent to the second surface 21B of the first substrate 21. In an embodiment, the first pass transistor group PTR Group-1 may be disposed inside the logic structure W1, and the second pass transistor group PTR Group-2 may be disposed adjacent to the second surface 21B of the first substrate 21. The first pass transistor group PTR Group-1 may include the first lower pass transistor 151, and the second pass transistor group PTR Group-2 may include the first upper pass transistor 63.

The first block switch BLKSW-1 may include at least one block selection transistor. For example, the first upper block switch transistor 67 and the first lower block switch transistor 171 may correspond to block selection transistors in the first block switch BLKSW-1. In an embodiment, the page buffer circuit 1140 may include the first upper page buffer transistor 65 and the first lower page buffer transistor 161.

Due to the disposition of the first upper pass transistor 63, the first upper page buffer transistor 65 and the first upper block switch transistor 67, the densities of the plurality of lower transistors 151, 161 and 171, the plurality of lower interconnections 183, the plurality of lower pads 184 and the plurality of upper pads 54 may be reduced.

Although exemplary embodiments of the disclosure have been described for illustrative purposes, those skilled in the art will appreciate that various modifications, additions and substitutions are possible, without departing from the scope and spirit of the disclosure. Therefore, the embodiments disclosed above and in the accompanying drawings should be considered in a descriptive sense only and not for limiting the technological scope. The technological scope of the disclosure is not limited by the embodiments and the accompanying drawings. The spirit and scope of the disclosure should be interpreted in connection with the appended claims and encompass all equivalents falling within the scope of the appended claims.

What is claimed is:

1. A semiconductor device comprising:
a first substrate having a first surface and a second surface facing opposite the first surface;
a stack structure disposed on the first surface of the first substrate, and including a plurality of interlayer insulating layers and a plurality of horizontal wiring layers that are alternately stacked, and a plurality of channel structures that pass through the plurality of interlayer insulating layers and the plurality of horizontal wiring layers;
a plurality of upper transistors on the second surface of the first substrate; and
a logic structure disposed on the stack structure, and including a plurality of lower transistors.

2. The semiconductor device according to claim 1, wherein
the plurality of upper transistors include an upper pass transistor, which is connected to a corresponding one among the plurality of horizontal wiring layers, and
the plurality of lower transistors include a lower pass transistor, which is connected to corresponding another among the plurality of horizontal wiring layers.

3. The semiconductor device according to claim 2,
wherein the stack structure further includes:
first and second contact plugs, each of which is connected to a corresponding one among the plurality of horizontal wiring layers; and
a first through electrode passing through the stack structure,
wherein the upper pass transistor is connected to the first contact plug via the first through electrode, and
wherein the lower pass transistor is connected to the second contact plug.

4. The semiconductor device according to claim 3, further comprising:
an interface between the logic structure and the stack structure;
a plurality of intermediate interconnections between the stack structure and the interface; and
a plurality of upper pads between the plurality of intermediate interconnections and the interface,
wherein the logic structure further includes a second substrate, a plurality of lower interconnections between the second substrate and the interface, and a plurality of lower pads between the plurality of lower interconnections and the interface, and
wherein the logic structure is bonded onto the stack structure.

5. The semiconductor device according to claim 4, wherein each of the plurality of upper pads directly contacts a corresponding one among the plurality of lower pads.

6. The semiconductor device according to claim 4, wherein the upper pass transistor is connected to the first contact plug via the first through electrode and the plurality of intermediate interconnections.

7. The semiconductor device according to claim 4, wherein the upper pass transistor is connected to the first contact plug via the first through electrode, the plurality of intermediate interconnections, the plurality of upper pads, the plurality of lower pads and the plurality of lower interconnections.

8. The semiconductor device according to claim 4, wherein the lower pass transistor is connected to the second contact plug via the plurality of lower interconnections, the plurality of lower pads, the plurality of upper pads and the plurality of intermediate interconnections.

9. The semiconductor device according to claim 2, further comprising:
a second through electrode passing through the stack structure,
wherein at least one among the plurality of upper transistors and the plurality of lower transistors further includes a block switch transistor that is connected to the upper pass transistor and the lower pass transistor via the second through electrode.

10. The semiconductor device according to claim 1, wherein at least one among the plurality of upper transistors and the plurality of lower transistors includes a plurality of page buffer transistors, which are connected to the plurality of channel structures.

11. The semiconductor device according to claim 1, further comprising:
a third through electrode passing through the stack structure,
wherein the plurality of upper transistors include an upper page buffer transistor that is connected to a corresponding one among the plurality of channel structures via the third through electrode, and
wherein the plurality of lower transistors include a lower page buffer transistor that is connected to corresponding another among the plurality of channel structures.

12. The semiconductor device according to claim 1, wherein
the stack structure further includes first to fourth contact plugs,
the stack structure includes a first cell area, a second cell area and a connection area between the first cell area and the second cell area, the plurality of channel structures are disposed in the first cell area and the second cell area, and the first to fourth contact plugs are disposed in the connection area,
the plurality of horizontal wiring layers include a first word line that is connected to the first and third contact plugs and a second word line that is connected to the second and fourth contact plugs,
the plurality of upper transistors include a first upper pass transistor that is connected to the first contact plug and a second upper pass transistor that is connected to the third contact plug, and the plurality of lower transistors include a first lower pass transistor that is connected to the second contact plug and a second lower pass transistor that is connected to the fourth contact plug,
a distance between the first contact plug and the first cell area is substantially the same as a distance between the third contact plug and the second cell area, and
a distance between the second contact plug and the first cell area is substantially the same as a distance between the fourth contact plug and the second cell area.

13. A semiconductor device comprising:
a first substrate having a first surface and a second surface that faces opposite the first surface;
a stack structure disposed on the first surface of the first substrate and including a plurality of interlayer insulating layers and a plurality of horizontal wiring layers that are alternately stacked, and a plurality of channel structures that pass through the plurality of interlayer insulating layers and the plurality of horizontal wiring layers, the stack structure having a cell area and a connection area that is continuous to the cell area, with the plurality of channel structures disposed in the cell area;
a plurality of upper transistors on the second surface of the first substrate;
a common source line disposed at substantially the same horizontal level as the first substrate on the stack structure, and connected to the plurality of channel structures; and
a logic structure bonded onto the stack structure, and including a plurality of lower transistors.

14. The semiconductor device according to claim 13, wherein the plurality of upper transistors are aligned at an upper part of the connection area.

15. The semiconductor device according to claim 13, wherein the common source line is aligned at an upper part of the cell area.

16. The semiconductor device according to claim 13, wherein
a lower surface of the common source line forms substantially the same plane as the first surface, and
an upper surface of the common source line forms substantially the same plane as the second surface.

17. The semiconductor device according to claim 13,
wherein each of the plurality of channel structures includes:
a core layer;
a channel layer outside the core layer;
a tunnel layer outside the channel layer;
a charge trap layer outside the tunnel layer; and
a blocking layer outside the charge trap layer, and
wherein the channel layer directly contacts the common source line.

18. The semiconductor device according to claim 17, wherein an uppermost end of the channel layer is at a level higher than a lowermost end of the common source line and the first surface.

19. The semiconductor device according to claim 17, wherein an uppermost end of the core layer is at a level higher than a lowermost end of the common source line and the first surface.

20. A semiconductor device comprising:
a first substrate having a first surface and a second surface that faces opposite the first surface;
a stack structure disposed on the first surface of the first substrate, and including a plurality of interlayer insulating layers and a plurality of horizontal wiring layers that are alternately stacked, and a plurality of channel structures that pass through the plurality of interlayer insulating layers and the plurality of horizontal wiring layers;
a plurality of upper transistors on the second surface of the first substrate; and
a common source line disposed at substantially the same horizontal level as the first substrate on the stack structure, and connected to the plurality of channel structures.
